(19) United States
(12) Patent Application Publication
(10) Pub. No.: US 2025/0159871 A1
(43) Pub. Date: May 15, 2025

(54) SEMICONDUCTOR MEMORY DEVICE AND MANUFACTURING METHOD THEREOF

(71) Applicant: Samsung Electronics Co., Ltd., Suwon-si (KR)

(72) Inventors: Young Jun KIM, Suwon-si (KR); Ga Eun CHOI, Suwon-si (KR); Ji Hoon SUNG, Suwon-si (KR); Kyu Hyun CHA, Suwon-si (KR)

(73) Assignee: Samsung Electronics Co., Ltd., Suwon-si (KR)

(21) Appl. No.: 18/664,850

(22) Filed: May 15, 2024

(30) Foreign Application Priority Data
Nov. 9, 2023 (KR) 10-2023-0154777

(51) Int. Cl. H10B 12/00

(52) U.S. Cl. CPC H10B 12/50; H10B 12/09; H10B 12/315

(57) ABSTRACT

A semiconductor memory device may include a substrate including a cell region, a peripheral region, and a boundary region therebetween, a plurality of gate electrodes extending in a first direction within the substrate of the cell region, a plurality of bit lines extending in a second direction crossing the first direction on the substrate of the cell region and the boundary region, a plurality of buried contacts connected to the substrate of the cell region and between the gate electrodes and between the bit lines on the substrate of the cell region, a dummy buried contact between the bit lines on the substrate of the boundary region, and a bit line contact connected to at least one of the bit lines on the substrate of the boundary region, wherein the dummy buried contact includes an insulating material.

### CROSS-REFERENCE TO RELATED APPLICATION

This application claims priority from Korean Patent Application No. 10-2023-0154777 filed on, Nov. 9, 2023 in the Korean Intellectual Property Office, and all the benefits accruing therefrom under 35 U.S.C. 119, the contents of which in their entirety are herein incorporated by reference.

### BACKGROUND

### Technical Field

The present disclosure relates to semiconductor memory devices and manufacturing methods thereof.

### Description of the Related Art

As semiconductor elements are gradually highly integrated, individual circuit patterns have become finer in order to implement more semiconductor elements in the same area. That is, as the degree of integration of the semiconductor element increases, design rules for components of the semiconductor element have decreased.

Meanwhile, in highly scaled semiconductor elements, a process of forming buried contacts in a boundary region between a cell region and a peripheral region and bit line contacts in the boundary region has become gradually complicated and difficult.

### SUMMARY

Some example embodiments of the present disclosure provide semiconductor memory devices with improved reliability.

Some example embodiments of the present disclosure provide manufacturing methods of a semiconductor memory device with improved reliability.

However, example embodiments of the present disclosure are not restricted to those set forth herein. The above and other example embodiments of the present disclosure will become more apparent to one of ordinary skill in the art to which the present disclosure pertains by referencing the detailed description of the present disclosure given below

According to an example embodiment of the present disclosure, a semiconductor memory device includes a substrate including a cell region, a peripheral region, and a boundary region between the cell region and the peripheral region, a plurality of gate electrodes extending in a first direction, within the substrate of the cell region, a plurality of bit lines extending in a second direction crossing the first direction, on the substrate of the cell region and the boundary region, a plurality of buried contacts connected to the substrate of the cell region and between the gate electrodes and between the bit lines, on the substrate of the cell region, a dummy buried contact between the bit lines, on the substrate of the boundary region and a bit line contact connected to at least one of the bit lines, on the substrate of the boundary region, wherein the dummy buried contact includes an insulating material.

According to an example embodiment of the present disclosure, a semiconductor memory device includes a substrate including a cell region, a peripheral region, and a boundary region between the cell region and the peripheral region, the cell region including a capacitor, the peripheral region including a peripheral circuit element, a plurality of gate electrodes extending in a first direction, within the substrate of the cell region, a plurality of first bit lines extending in a second direction crossing the first direction, on the substrate of the cell region, a plurality of second bit lines connected to the first bit lines, respectively, on the substrate of the boundary region, a plurality of fences and a plurality of buried contacts alternately arranged in the second direction, between the first bit lines, a dummy buried contact between the second bit lines and a bit line contact in contact with at least some of the second bit lines, on the substrate of the boundary region, wherein a width of a respective one of the first bit lines in the first direction is smaller than a width of a respective one of the second bit lines in the first direction, and the dummy buried contact includes an insulating material.

According to an example embodiment of the present disclosure, a semiconductor memory device includes a substrate including a cell region, a peripheral region, and a boundary region between the cell region and the peripheral region, a peripheral circuit element disposed on the substrate of the peripheral region, a plurality of gate electrodes extending in a first direction, within the substrate of the cell region, a plurality of bit lines extending in a second direction crossing the first direction, on the substrate of the cell region and the boundary region, a plurality of buried contacts on the substrate of the cell region and spaced apart from each other in the second direction, the buried contacts connected to the substrate of the cell region, the buried contacts being between the gate electrodes and between the bit lines, a plurality of capacitors connected to the buried contacts, respectively, on the substrate of the cell region, a plurality of fences between the buried contacts and between the gate electrodes, the fences spaced apart from each other in the second direction and being on the substrate of the cell region, a dummy buried contact between the bit lines, on the substrate of the boundary region and a bit line contact connected to at least one of the bit lines, on the substrate of the boundary region, wherein a first distance from an upper surface of a respective one of the buried contacts to a bottom surface of the respective one of the buried contact is smaller than a second distance from the upper surface of the respective one of the buried contacts to a bottom surface of a respective one of the fences, at least a portion of the dummy buried contact is in contact with the substrate of the boundary region, and the dummy buried contacts and the fences include a same material.

According to an example embodiment of the present disclosure, a manufacturing method of a semiconductor memory device includes providing a substrate including a cell region, a peripheral region, and a boundary region between the cell region and the peripheral region, forming a plurality of gate electrodes within the substrate of the cell region, the gate electrodes extending in a first direction, forming a plurality of bit lines on the substrate of the cell region and the boundary region, the bit lines extending in a second direction crossing the first direction, forming a pre-buried contact between the bit lines on the substrate of the cell region and a portion of the boundary region, forming a mask film on the substrate of the cell region, forming a second trench on the cell region and forming a first trench on the boundary region by removing the pre-buried contact using the mask film as an etching mask, forming a fence within the second trench and forming a dummy buried contact within the first trench, wherein the fence and the dummy buried contact each include an insulating material.

According to an example embodiment of the present disclosure, a manufacturing method of a semiconductor memory device includes providing a substrate including a cell region, a peripheral region, and a boundary region between the cell region and the peripheral region, forming a plurality of gate electrodes within the substrate of the cell region, the gate electrodes extending in a first direction, forming a plurality of bit lines on the substrate of the cell region and the boundary region, the bit lines extending in a second direction crossing the first direction, forming a pre-buried contact between the bit lines on the substrate of the cell region and a portion of the boundary region, forming a dummy buried contact by etching a portion of the pre-buried contact on the substrate of the boundary region, forming a plurality of buried contacts by etching the pre-buried contact on the substrate of the cell region after the forming of the dummy buried contact and forming a fence between the buried contacts, wherein the fence and the dummy buried contact each include an insulating material.

### BRIEF DESCRIPTION OF THE DRAWINGS

The above and other aspects and features of the present disclosure will become more apparent by describing in detail some example embodiments thereof with reference to the attached drawings, in which:

FIG. 1 is a block diagram of a semiconductor memory device according to an example embodiment of the present disclosure.

FIG. 2 is a plan view of the semiconductor memory device according to an example embodiment of the present disclosure.

FIG. 3 is a cross-sectional view taken along line A-A of FIG. 2.

FIG. 4 is a cross-sectional view taken along line B-B in FIG. 2.

FIG. 5 is a cross-sectional view taken along line C-C in FIG. 2.

FIG. 6 is a cross-sectional view taken along line D-D in FIG. 2.

FIGS. 7 to 13 are views for describing a semiconductor memory device according to some example embodiments of the present disclosure.

FIG. 14 is a plan view of a semiconductor memory device according to an example embodiment of the present disclosure.

FIG. 15 is a cross-sectional view taken along line E-E in FIG. 14.

FIGS. 16 to 22 are views for describing intermediate steps of a manufacturing method of a semiconductor memory device according to an example embodiment of the present disclosure.

FIGS. 23 to 28 are views for describing intermediate steps of a manufacturing method of a semiconductor memory device according to an example embodiment of the present disclosure.

FIGS. 29 to 35 are views for describing intermediate steps of a manufacturing method of a semiconductor memory device according to an example embodiment of the present disclosure.

### DETAILED DESCRIPTION

The terms “first”, “second”, and the like as used herein are used to describe various elements or components, but these elements or components are not limited by these terms. These terms are used only in order to distinguish one element or component from another element or component. Accordingly, a first element or component mentioned below may also be a second element or component within the inventive concepts of the present disclosure.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C, or any combination thereof. Likewise, A and/or B means A, B, or A and B.

Hereinafter, some example embodiments according to the inventive concepts of the present disclosure will be described with reference to the accompanying drawings.

In the drawings of semiconductor memory devices according to some example embodiments, a dynamic random access memory (DRAM) has been illustrated by way of example, but the present disclosure is not limited thereto.

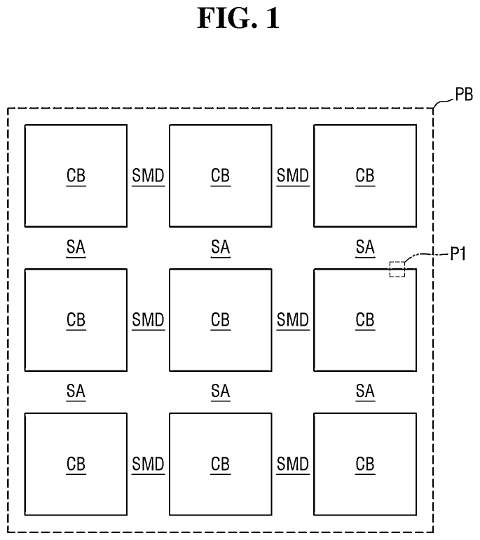

First, semiconductor memory devices according to some example embodiments will be described with reference to FIGS. 1 to 6.

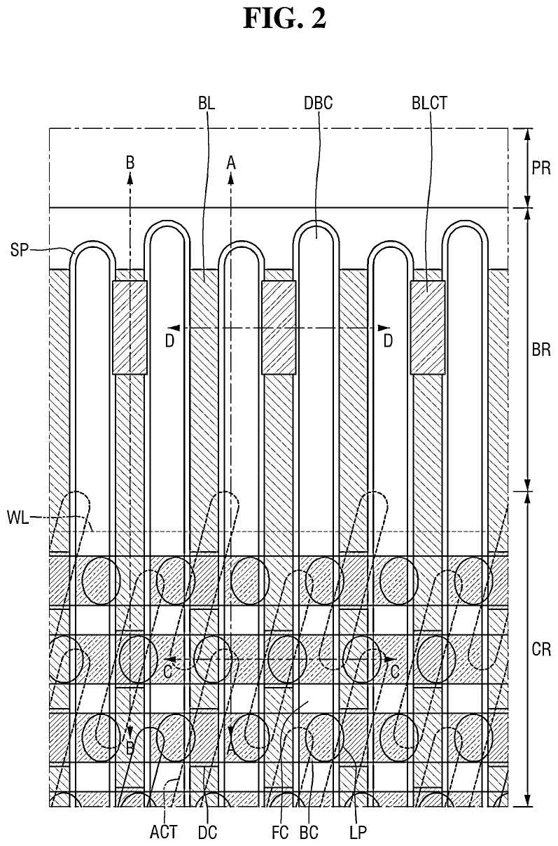

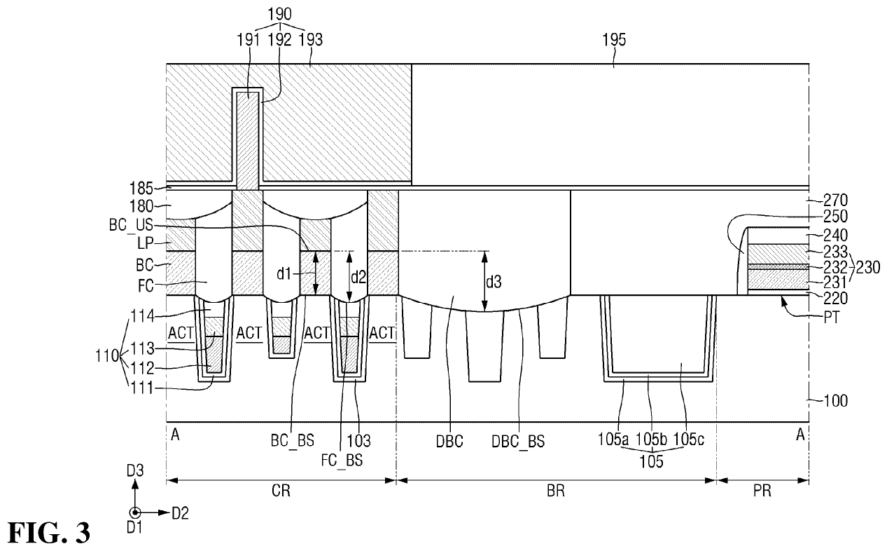

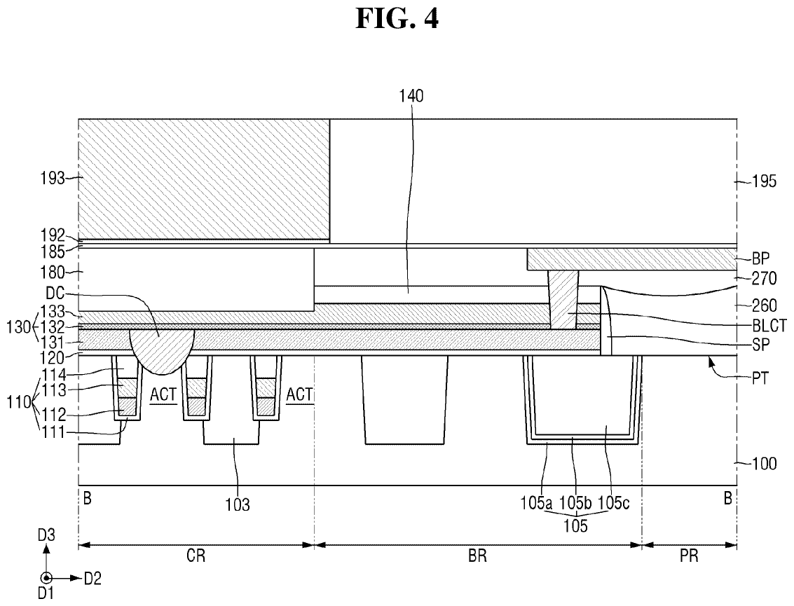

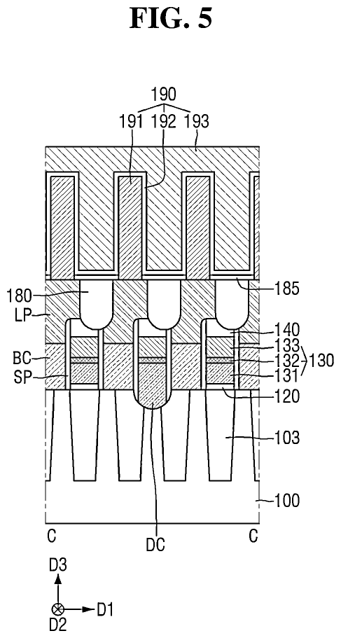

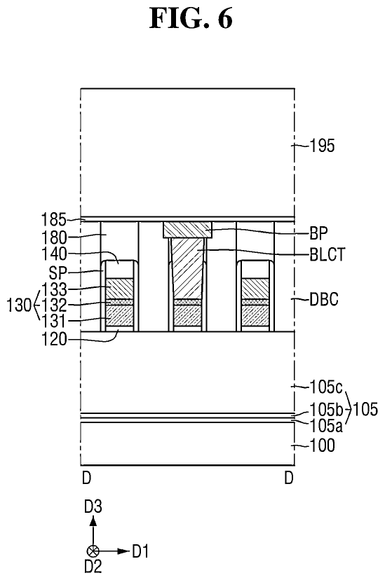

FIG. 1 is a block diagram of a semiconductor memory device according to an example embodiment of the present disclosure. FIG. 2 is a plan view of the semiconductor memory device according to an example embodiment of the present disclosure. FIG. 3 is a cross-sectional view taken along line A-A of FIG. 2. FIG. 4 is a cross-sectional view taken along line B-B in FIG. 2. FIG. 5 is a cross-sectional view taken along line C-C in FIG. 2. FIG. 6 is a cross-sectional view taken along line D-D in FIG. 2. For reference, FIG. 2 may be a plan view corresponding to portion P1 of FIG. 1.

First, referring to FIG. 1, the semiconductor memory device may include cell blocks CB and a peripheral block PB surrounding each of the cell blocks CB. Each of the cell blocks CB may include a cell circuit such as a memory integrated circuit. The peripheral block PB may include various peripheral circuits required for an operation of the cell circuit. The peripheral circuits may be electrically connected to the cell circuit.

The peripheral block PB may include sense amplifier circuits SA and sub-word line driver circuits SWD. As an example, the sense amplifier circuits SA may face each other with the cell blocks CB interposed therebetween. The sub-word line driver circuits SWD may face each other with the cell blocks CB interposed therebetween. The peripheral block PB may further include a power source for driving sense amplifiers and ground driver circuits, but inventive concepts of the present disclosure are not limited thereto.

Referring to FIGS. 2 to 6, a substrate 100 may be provided. The substrate 100 may include a cell region CR, a boundary region BR, and a peripheral region PR.

The cell region CR may be a region where a plurality of memory cells are provided. The boundary region BR may be provided around the cell region CR. The peripheral region PR may be a region where a peripheral circuit operating the plurality of memory cells within the cell region CR is provided. For example, the boundary region BR may be provided between the peripheral region PR and the cell region CR. The boundary region BR may be a region for connecting a structure disposed in the cell region CR and a structure in the peripheral region PR to each other.

The substrate 100 may be, for example, a silicon single crystal substrate or a silicon on insulator (SOI) substrate. In some example embodiments, the substrate 100 may include silicon germanium, silicon germanium on insulator (SGOI), indium antimonide, a lead tellurium compound, indium arsenide, indium phosphide, gallium arsenide, or gallium antimonide, but is not limited thereto.

Cell element isolation films 103 may be provided within the substrate 100 of the cell region CR. The cell element isolation film 103 may include a silicon oxide film, a silicon nitride film, a silicon oxynitride film, and combinations thereof, but is not limited thereto.

Boundary element isolation films 105 may be provided within the substrate 100 of the boundary region BR. In some example embodiments, the boundary element isolation film 105 may include a first liner film 105a, a second liner film 105b, and a buried insulating film 105c. The first liner film 105a may be conformally formed on inner sidewalls and a bottom surface of a trench formed within the substrate 100 of the boundary region BR. The buried insulating film 105c may fill the trench. The second liner film 105b may be interposed between the first liner film 105a and the buried insulating film 105c.

The first liner film 105a may be formed as a silicon oxide film. The second liner film 105b may be formed as a silicon nitride film. The buried insulating film 105c may be formed as a silicon oxide film.

The cell region CR may include a plurality of active regions ACT. The plurality of active regions ACT may be defined by the cell element isolation films 103 and/or the boundary element isolation films 105. In accordance with a decrease in design rule of the semiconductor memory device, each of the plurality of active regions ACT may be disposed in a bar shape of a diagonal line or an oblique line as illustrated in FIG. 2. For example, the active region ACT may extend in a fourth direction D4.

The plurality of active regions ACT may be arranged parallel to each other in a first direction D1. An end of one active region ACT may be arranged adjacent to the center of another active region ACT neighboring the one active region ACT. In the present specification, the first direction D1, a second direction D2, a third direction D3, and the fourth direction D4 may cross each other. The first direction D1, the second direction D2, and the third direction D3 may be substantially perpendicular to each other. The fourth direction D4 may be put on the same plane as the first direction D1 and the second direction D2. That is, the fourth direction D4 may be any direction between the first direction D1 and the second direction D2.

Semiconductor memory devices according to some example embodiments may include various contact arrangements formed on the active regions ACT. The various contact arrangements may include, for example, direct contacts DC, buried contacts BC, and landing pads LP, and the like.

Here, the direct contact DC may refer to a contact electrically connecting each of the plurality of active regions ACT to a bit line BL. The buried contact BC may refer to a contact connecting each of the plurality of active regions ACT to a capacitor lower electrode 191. Due to an arrangement structure, contact areas between the buried contacts BC and the plurality of active regions ACT may be small. Accordingly, the landing pads LP having conductivity may be introduced in order to increase contact areas with the plurality of active regions ACT and increase a contact area with the capacitor lower electrode 191.

The landing pads LP may be disposed between the plurality of active regions ACT and the buried contacts BC or disposed between the buried contacts BC and the capacitor lower electrode 191. According to some example embodiments, the landing pad LP may be disposed between the buried contact BC and the capacitor lower electrode 191. Contact resistance between the plurality of active regions ACT and the capacitor lower electrode 191 may be decreased by increasing the contact areas through the introduction of the landing pads LP.

Word lines WL may be buried in the substrate 100 of the cell region CR. The word lines WL may traverse the plurality of active regions ACT. The word lines WL may extend in the first direction D1. The word lines WL may be spaced apart from each other in the second direction D2. The word lines WL may be buried in the substrate 100 and extend in the first direction D1. Although not illustrated, an impurity region may be formed within the substrate 100 between the word lines WL. The impurity region may be doped with N-type impurities.

According to some example embodiments, a semiconductor memory device may include a plurality of word line structures 110. Each of the plurality of word line structures 110 may be buried in the substrate 100 and extend in the first direction D1. The plurality of word line structures 110 may be spaced apart from each other in the second direction D2.

Each of the plurality of word line structures 110 may include a gate insulating film 111, a gate electrode 112, and gate capping films 113 and 114. The gate electrode 112 of the word line structure 110 may correspond to the word line WL of the semiconductor memory device. Each of the plurality of word line structures 110 may be provided within a gate trench formed within the substrate 100.

The gate insulating film 111 may extend along inner sidewalls and a bottom surface of the gate trench. The gate insulating film 111 may extend along at least a portion of a profile of the gate trench.

The gate insulating film 111 may include, for example, at least one of silicon oxide, silicon nitride, silicon oxynitride, or a high-k material having a higher dielectric constant than silicon oxide. The high-k material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

The gate electrode 112 may be disposed on the gate insulating film 111. The gate electrode 112 may fill a portion of the gate trench.

The gate electrode 112 may include at least one of metal, a metal alloy, conductive metal nitride, conductive metal carbonitride, conductive metal carbide, metal silicide, a doped semiconductor material, conductive metal oxynitride, or conductive metal oxide. The gate electrode 112 may include, for example, at least one of TIN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, NiPt, Nb, NbN, NbC, Mo, MoN, MoC, WC, Rh, Pd, Ir, Ag, Au, Zn, V, RuTiN, TiSi, TaSi, NiSi, CoSi, IrOx, RuOx, or combinations thereof, but is not limited thereto.

The gate capping films 113 and 114 may be disposed on the gate electrode 112. The gate capping films 113 and 114 may fill the gate trench remaining after the gate insulating film 111 and the gate electrode 112 are formed.

In some example embodiments, the gate capping films 113 and 114 may include a gate capping conductive film 113 and a gate capping insulating film 114. The gate capping conductive film 113 and the gate capping insulating film 114 may be sequentially stacked. That is, the gate capping insulating film 114 is disposed on the gate capping conductive film 113. The gate capping conductive film 113 may include, for example, polysilicon or polysilicon-germanium, but is not limited thereto. The gate capping insulating film 114 may include, for example, at least one of silicon nitride (SIN), silicon oxynitride (SiON), silicon oxide (SiO₂), silicon carbonitride (SiCN), silicon oxycarbonitride (SiOCN), or combinations thereof.

A cell buffer film 120 may be provided on the substrate 100 of the cell region CR. Although not illustrated, the cell buffer film 120 may include first to third insulating films that are sequentially stacked. The second insulating film may include a material having an etch selectivity with respect to the first and third insulating films. For example, the second insulating film may include silicon nitride, and the first and third insulating films may include silicon oxide.

A plurality of bit lines BL may be disposed on the substrate 100. The bit lines BL may be disposed on the cell buffer film 120. The bit lines BL may traverse the word line WL. The bit lines BL may extend in the second direction D2. In addition, the bit lines BL may be spaced apart from each other in the first direction D1. The bit line BL may correspond to a bit line structure 130 to be described later.

The bit line structure 130 may include a bit line lower electrode 131, a bit line middle electrode 132, and a bit line upper electrode 133 that are sequentially stacked. The bit line lower electrode 131 may include polysilicon doped with impurities. The bit line middle electrode 132 may include TiSiN. The bit line upper electrode 133 may include tungsten (W). However, the inventive concepts of the present disclosure are not limited thereto. A bit line capping pattern 140 may be disposed on the bit line structure 130. The bit line capping pattern 140 may include silicon nitride.

Bit line spacers SP may be disposed on sidewalls of the bit line structure 130 and sidewalls of the bit line capping pattern 140. In FIG. 4, the bit line spacer SP may be disposed on the substrate 100 and the cell element isolation film 103 in a portion of the bit line structure 130 where the direct contact DC is formed. However, in a portion where the direct contact DC is not formed, the bit line spacer SP may be disposed on the cell buffer film 120.

As illustrated, the bit line spacer SP may be a single layer, but the inventive concepts of the present disclosure is not limited thereto. The bit line spacer SP may also be multiple layers. The bit line spacer SP may include, for example, one of a silicon oxide film, a silicon nitride film, a silicon oxynitride film (SiON), a silicon oxycarbonitride film (SiOCN), air, or combinations thereof, but is not limited thereto.

The cell buffer film 120 may be interposed between the bit line structure 130 and the cell element isolation film 103 and between the bit line spacer SP and the substrate 100.

The bit line BL may be electrically connected to an impurity region of the active region ACT through the direct contact DC. For example, the direct contact DC may be made of polysilicon doped with impurities.

The buried contact BC may be disposed between a pair of bit lines BL adjacent to each other. The buried contacts BC may be spaced apart from each other. The buried contact BC may include at least one of polysilicon doped with impurities, a conductive silicide compound, conductive metal nitride, or metal. The buried contacts BC may have an island shape in which the buried contacts BC are spaced apart from each other in plan view. The buried contacts BC may penetrate through the cell buffer film 120 to be in contact with the impurity regions of the active region ACT.

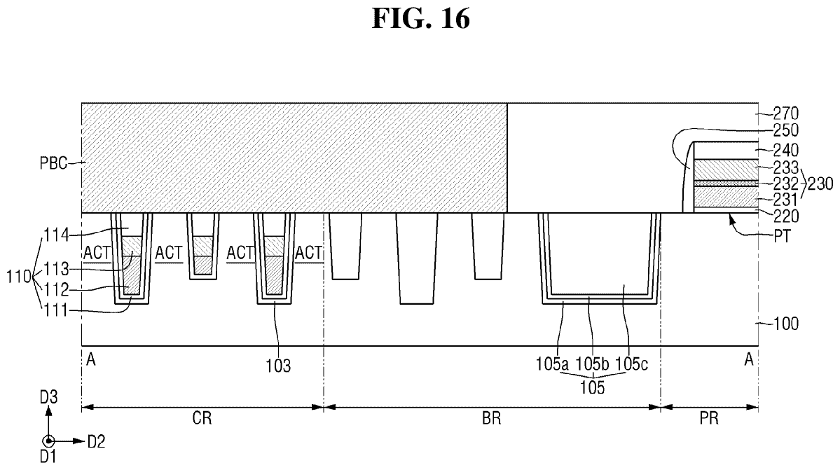

In some example embodiments, a pre-buried contact PBC (see FIG. 16) may be formed to be elongated in the second direction D2, and fences FC may be formed by removing the pre-buried contact PBC. Accordingly, although not illustrated, a seam elongated in the second direction D2 may be disposed within the buried contact BC. However, the inventive concepts of the present disclosure is not limited thereto.

The landing pad LP may be formed on the buried contact BC. The landing pad LP may be electrically connected to the buried contact BC. The landing pad LP may overlap a portion of an upper surface of the bit line BL. The landing pad LP may include, for example, at least one of a semiconductor material doped with impurities, a conductive silicide compound, conductive metal nitride, conductive metal carbide, metal, or a metal alloy.

The fence FC may be disposed on the substrate 100 and the cell element isolation film 103. The fence FC may be disposed on the word line structure 110. The fence FC may overlap the word line structure 110 formed within the substrate 100. The fence FC may be disposed between a pair of bit lines BL extending in the second direction D2. The fence FC may be disposed between a pair of bit line structures 130 extending in the second direction D2.

The fence FC may also be interposed between the buried contacts BC. That is, the fences FC and the buried contacts BC may be alternately arranged in the second direction D2. The fence FC may include an insulating material. The fence FC may include, for example, at least one of silicon oxide, silicon nitride, silicon oxynitride, or combinations thereof. As an example, the fence FC may be formed as a silicon nitride film.

A pad isolation insulating film 180 may be formed on the landing pad LP and the bit line structure 130. For example, the pad isolation insulating film 180 may be disposed on the bit line capping pattern 140. The pad isolation insulating film 180 may define an isolated region in which the landing pad LP is to be provided. In addition, the pad isolation insulating film 180 may not cover an upper surface of the landing pad LP.

The pad isolation insulating film 180 may include an insulating material and may electrically isolate a plurality of landing pads LP from each other. For example, the pad isolation insulating film 180 may include, for example, at least one of a silicon oxide film, a silicon nitride film, a silicon oxynitride film, a silicon oxycarbonitride film, or a silicon carbonitride film.

An etch stop film 185 may be disposed on the pad isolation insulating film 180 and the landing pad LP. The etch stop film 185 may include at least one of a silicon nitride film, a silicon carbonitride film, a silicon boron nitride film (SiBN), a silicon oxynitride film, or a silicon oxycarbide film.

A capacitor 190 may be disposed on the landing pad LP. The capacitor 190 may be electrically connected to the landing pad LP. A portion of the capacitor 190 may be disposed within the etch stop film 185. The capacitor 190 includes the capacitor lower electrode 191, a capacitor dielectric film 192, and a capacitor upper electrode 193.

The capacitor lower electrode 191 may be disposed on the landing pad LP. It has been illustrated that the capacitor lower electrode 191 has a pillar shape, but example embodiments of the present disclosure are not limited thereto. In some example embodiments, the capacitor lower electrode 191 may have a cylindrical shape. The capacitor dielectric film 192 is formed on the capacitor lower electrode 191. The capacitor dielectric film 192 may be formed along a profile of the capacitor lower electrode 191. The capacitor upper electrode 193 is formed on the capacitor dielectric film 192. The capacitor upper electrode 193 may surround outer sidewalls of the capacitor lower electrode 191.

As an example, the capacitor dielectric film 192 may be disposed in a portion that vertically overlaps the capacitor upper electrode 193. As another example, unlike illustrated, the capacitor dielectric film 192 may include a portion that vertically overlaps the capacitor upper electrode 193 and a portion that does not vertically overlap the capacitor upper electrode 193. That is, the portion of the capacitor dielectric film 192 that does not vertically overlap the capacitor upper electrode 193 is a portion of the capacitor dielectric film 192 that is not covered by the capacitor upper electrode 193.

The capacitor lower electrode 191 and the capacitor upper electrode 193 may each include, for example, a doped semiconductor material, conductive metal nitride (e.g., titanium nitride, tantalum nitride, niobium nitride, tungsten nitride, etc.), a metal (e.g., ruthenium, iridium, titanium, tantalum, etc.), and conductive metal oxide (e.g., iridium oxide, niobium oxide, etc.), or the like, but are not limited thereto.

The capacitor dielectric film 192 may include, for example, one of silicon oxide, silicon nitride, silicon oxynitride, a high-k material, or combinations thereof, but is not limited thereto. According to some example embodiments, the capacitor dielectric film 192 may have a stacked film structure in which zirconium oxide, aluminum oxide, and zirconium oxide are sequentially stacked. According to some example embodiments, the capacitor dielectric film 192 may include a dielectric film including hafnium (Hf). According to some example embodiments, the capacitor dielectric film 192 may have a stacked film structure of a ferroelectric material film and a paraelectric material film.

In some example embodiments, a dummy buried contact DBC may be provided. The dummy buried contact DBC may be disposed on the substrate 100 of the boundary region BR. The dummy buried contact DBC may be disposed on the boundary element isolation film 105 within the substrate 100 of the boundary region BR. At least a portion of the dummy buried contact DBC may overlap a bit line contact BLCT to be described later in the first direction D1. The dummy buried contact DBC may be interposed between adjacent bit line contacts BLCT.

The dummy buried contact DBC may be made of an insulating material. For example, the dummy buried contact DBC may include a silicon nitride film, a silicon oxide film, a silicon oxynitride film, and/or combinations thereof. Because the dummy buried contact DBC is made of the insulating material, a short-circuit may not occur even though the bit line contact BLCT and the dummy buried contact DBC are in contact with each other. Accordingly, the semiconductor memory device with improved reliability may be manufactured.

In some example embodiments, the dummy buried contact DBC and the fence FC may be formed through the same process. That is, the dummy buried contact DBC and the fence FC may include the same material. As an example, the dummy buried contact DBC and the fence FC may each be formed as a silicon nitride film, but the inventive concepts of the present disclosure are not limited thereto.

In some example embodiments, the buried contact BC includes an upper surface BC_US and a bottom surface BC_BS. The upper surface BC_US of the buried contact BC may face the capacitor 190. The bottom surface BC_BS of the buried contact BC may face the capacitor 190.

In some example embodiments, a first distance d1 from the upper surface BC_US of the buried contact BC to the bottom surface BC_BS of the buried contact BC in the third direction D3 is smaller than a second distance d2 from the upper surface BC_US of the buried contact BC to a bottom surface FC_BS of the fence FC in the third direction D3.

This may be because the fence FC is formed by etching a portion of the pre-buried contact PBC (see FIG. 16). The bottom surface FC_BS of the fence FC may face the capacitor 190. It has been illustrated that the bottom surface FC_BS of the fence FC is convex with respect to the capacitor 190, but the inventive concepts of the present disclosure are not limited thereto.

In some example embodiments, the first distance d1 from the upper surface BC_US of the buried contact BC to the bottom surface BC_BS of the buried contact BC in the third direction D3 is smaller than a third distance d3 from the upper surface BC_US of the buried contact BC to a bottom surface DBC_BS of the dummy buried contact DBC in the third direction D3.

This may be because the dummy buried contact DBC is formed by etching a portion of the pre-buried contact PBC (see FIG. 16). The bottom surface DBC_BS of the dummy buried contact DBC may face the capacitor 190. It has been illustrated that the bottom surface DBC_BS of the dummy buried contact DBC is convex with respect to the capacitor 190, but the inventive concepts of the present disclosure are not limited thereto.

In other words, a level of the bottom surface BC_BS of the buried contact BC is different from a level of the bottom surface FC_BS of the fence FC. In addition, the level of the bottom surface BC_BS of the buried contact BC is different from a level of the bottom surface DBC_BS of the dummy buried contact DBC. In addition, the level of the bottom surface FC_BS of the fence FC is different from the level of the bottom surface DBC_BS of the dummy buried contact DBC.

In some example embodiments, the second distance d2 may be smaller than the third distance d3. This may be because a width of the fence FC in the second direction D2 is smaller than a width of the dummy buried contact DBC in the second direction D2. However, the inventive concepts of the present disclosure are not limited thereto.

According to some example embodiments, a semiconductor memory device may further include the bit line contact BLCT and a bit line pad BP.

The bit line contact BLCT may be disposed on the substrate 100 of the boundary region BR. The bit line contact BLCT may penetrate through the bit line capping pattern 140 to be electrically connected to the bit line structure 130 or the bit line BL. It has been illustrated in FIG. 4 that the bit line contact BLCT penetrates through the bit line capping pattern 140, the bit line upper electrode 133, and the bit line middle electrode 132, but the inventive concepts of the present disclosure are not limited thereto.

The bit line pad BP may be disposed on the bit line contact BLCT. The bit line pad BP may be formed through the same process as the landing pad LP described above. A level of an upper surface of the bit line pad BP may be the same as a level of the upper surface of the landing pad LP, but is not limited thereto. Likewise, the level of the upper surface of the bit line pad BP may be the same as a level of an upper surface of the pad isolation insulating film 180.

In FIG. 6, the bit line contact BLCT may not be in contact with the dummy buried contact DBC. However, at least a portion of the bit line pad BP may be in contact with the dummy buried contact DBC. Because the dummy buried contact DBC is made of the insulating material, a short-circuit may not occur even though the bit line pad BP and the dummy buried contact DBC are in contact with each other.

In FIG. 2, the bit line contact BLCT may not be formed on one of a pair of bit lines BL that are most adjacent to each other in the first direction D1. For example, the bit line contact BLCT may include a first contact connected to one of the plurality of bit lines BL and a second contact connected to the other of the plurality of bit lines BL. One or more bit lines BL may be disposed between the first contact and the second contact. However, the inventive concepts of the present disclosure are not limited thereto.

The bit line contact BLCT and the bit line pad BP may each include a conductive material. The bit line contact BLCT and the bit line pad BP may each include, for example, at least one of a semiconductor material doped with impurities, a conductive silicide compound, conductive metal nitride, conductive metal carbide, metal, or a metal alloy.

According to some example embodiments a semiconductor memory device may further include a first interlayer insulating film 260, a second interlayer insulating film 270, and a third interlayer insulating film 195.

The first interlayer insulating film 260 may be disposed on the bit line spacer SP. The first interlayer insulating film 260 may be disposed on a portion of the boundary element isolation film 105 and the substrate 100 of the peripheral region PR. The first interlayer insulating film 260 may include an insulating material. For example, the first interlayer insulating film 260 may be formed as a silicon oxide film.

The second interlayer insulating film 270 may be disposed on the bit line structure 130. The second interlayer insulating film 270 may also be disposed on the first interlayer insulating film 260. The second interlayer insulating film 270 may surround at least a portion of the bit line contact BLCT and may surround at least a portion of the bit line pad BP. The second interlayer insulating film 270 may include an insulating material. For example, the second interlayer insulating film 270 may be formed as a silicon nitride film.

The third interlayer insulating film 195 may be disposed on the etch stop film 185. The third interlayer insulating film 195 may cover sidewalls of the capacitor upper electrode 193. The third interlayer insulating film 195 may include an insulating material. For example, the third interlayer insulating film 195 may be formed as a silicon oxide film.

In some example embodiments, a peripheral circuit element PT may be provided on the substrate 100 of the peripheral region PR.

Although not illustrated, a peripheral element isolation film may be provided within the substrate 100 of the peripheral region PR. The peripheral element isolation film may define a peripheral active region. The peripheral circuit element PT may be provided on the peripheral active region.

The peripheral circuit element PT may include a peripheral gate insulating film 220, a peripheral gate structure 230, a peripheral gate capping pattern 240, and a peripheral gate spacer 250. Components of the peripheral gate structure 230 may be disposed at substantially the same levels as components of the bit line structure 130, respectively. The peripheral gate insulating film 220 may be disposed at substantially the same level as the cell buffer film 120. The peripheral gate capping pattern 240 may be disposed at substantially the same level as the bit line capping pattern 140.

The peripheral gate insulating film 220 may extend along the substrate 100 of the peripheral region PR. The peripheral gate insulating film 220 may include, for example, silicon oxide, silicon nitride, silicon oxynitride, or a high-k material having a higher dielectric constant than silicon oxide.

The peripheral gate structure 230 may include first to third conductive films 231, 232, and 233 that are sequentially stacked. The first conductive film 231 may be disposed on the peripheral gate insulating film 220. The second conductive film 232 may be disposed on the first conductive film 231. The third conductive film 233 may be disposed on the second conductive film 232. The first conductive film 231 may be formed through the same process as the bit line lower electrode 131. The second conductive film 232 may be formed through the same process as the bit line middle electrode 132. The third conductive film 233 may be formed through the same process as the bit line upper electrode 133. Accordingly, a thickness of the first conductive film 231 in the third direction D3 may be substantially the same as a thickness of the bit line lower electrode 131 in the third direction D3. Likewise, a thickness of the second conductive film 232 in the third direction D3 may be substantially the same as a thickness of the bit line middle electrode 132 in the third direction D3. A thickness of the third conductive film 233 in the third direction D3 may be substantially the same as a thickness of the bit line upper electrode 133 in the third direction D3.

The first conductive film 231 may include polysilicon doped with impurities. The second conductive film 232 may include TiSiN. The third conductive film 233 may include tungsten (W). However, the inventive concepts of the present disclosure are not limited thereto.

The peripheral gate capping pattern 240 is disposed on the peripheral gate structure 230. The peripheral gate capping pattern 240 may be formed through substantially the same process as the bit line capping pattern 140. Accordingly, a thickness of the peripheral gate capping pattern 240 in the third direction D3 may be substantially the same as a thickness of the bit line capping pattern 140 in the third direction D3. The peripheral gate capping pattern 240 may include, for example, silicon nitride.

The peripheral gate spacer 250 may be disposed on a sidewall of the peripheral gate structure 230 and a sidewall of the peripheral gate capping pattern 240. The peripheral gate spacer 250 may include, for example, one of a silicon oxide film, a silicon nitride film, a silicon oxynitride film (SiON), a silicon oxycarbonitride film (SiOCN), air, or combinations thereof, but is limited thereto.

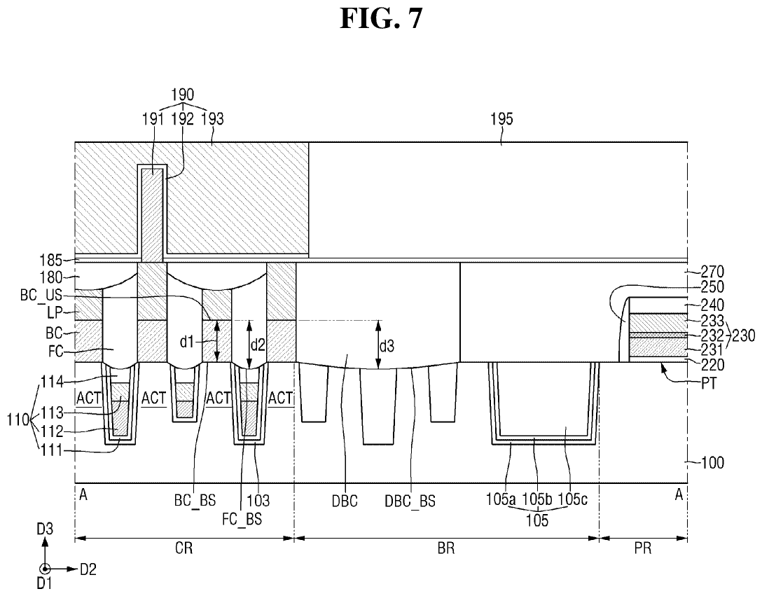

Hereinafter, semiconductor memory devices according to some example embodiments of the present disclosure will be described with reference to FIGS. 7 to 13. For convenience of explanation, contents overlapping those described with reference to FIGS. 1 to 6 will be briefly described or a description thereof will be omitted.

FIGS. 7 to 13 are views for describing semiconductor memory devices according to some other example embodiments of the present disclosure.

First, referring to FIG. 7, the second distance d2 from the upper surface BC_US of the buried contact BC to the bottom surface FC_BS of the fence FC in the third direction D3 may be equal to the third distance d3 from the upper surface BC_US of the buried contact BC to the bottom surface DBC_BS of the dummy buried contact DBC in the third direction D3.

That is, the level of the bottom surface FC_BS of the fence FC may be the same as the level of the bottom surface DBC_BS of the dummy buried contact DBC. This may be because the fence FC and the dummy buried contact DBC are formed through the same process.

In this case, the first distance d1 from the upper surface BC_US of the buried contact BC to the bottom surface BC_BS of the buried contact BC in the third direction D3 may be smaller than the second distance d2 and the third distance d3. In addition, the level of the bottom surface BC_BS of the buried contact BC may be higher than the level of the bottom surface FC_BS of the fence FC than the level of the bottom surface DBC_BS of the dummy buried contact DBC.

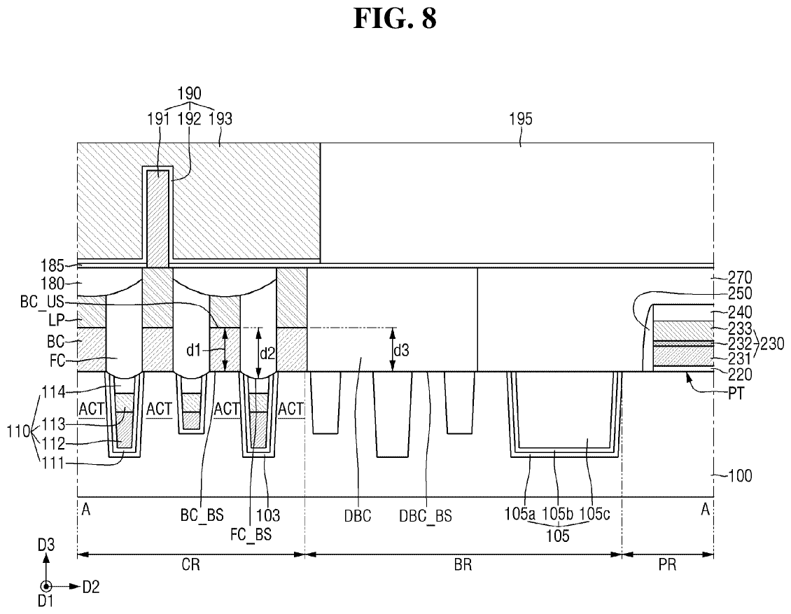

Referring to FIG. 8, the first distance d1 from the upper surface BC_US of the buried contact BC to the bottom surface BC_BS of the buried contact BC in the third direction D3 may be equal to the third distance d3 from the upper surface BC_US of the buried contact BC to the bottom surface DBC_BS of the dummy buried contact DBC in the third direction D3.

That is, the level of the bottom surface BC_BS of the buried contact BC may be the same as the level of the bottom surface DBC_BS of the dummy buried contact DBC. In this case, the second distance d2 from the upper surface BC_US of the buried contact BC to the bottom surface FC_BS of the fence FC in the third direction D3 may be greater than the first distance d1 and the third distance d3.

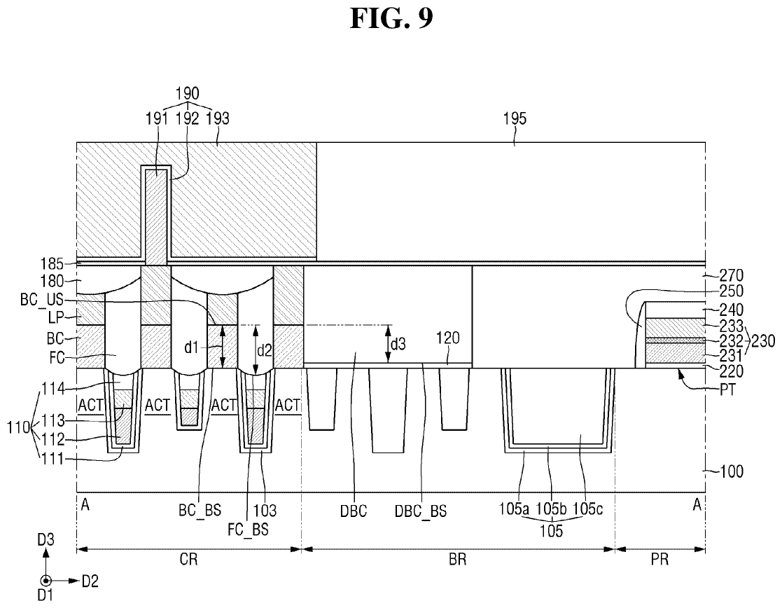

Referring to FIG. 9, the cell buffer film 120 may be interposed between the substrate 100 of the boundary region BR and the dummy buried contact DBC. In a process of forming the dummy buried contact DBC, the cell buffer film 120 on the substrate 100 of the boundary region BR may not be removed. Accordingly, on the substrate 100 of the boundary region BR, the dummy buried contact DBC may be formed on the cell buffer film 120.

In this case, the third distance d3 from the upper surface BC_US of the buried contact BC to the bottom surface DBC_BS of the dummy buried contact DBC in the third direction D3 is smaller than the first distance d1 from the upper surface BC_US of the buried contact BC to the bottom surface BC_BS of the buried contact BC in the third direction D3. In this case, the third distance d3 may be smaller than the second distance d2 from the upper surface BC_US of the buried contact BC to the bottom surface FC_BS of the Fence FC in the third direction D3.

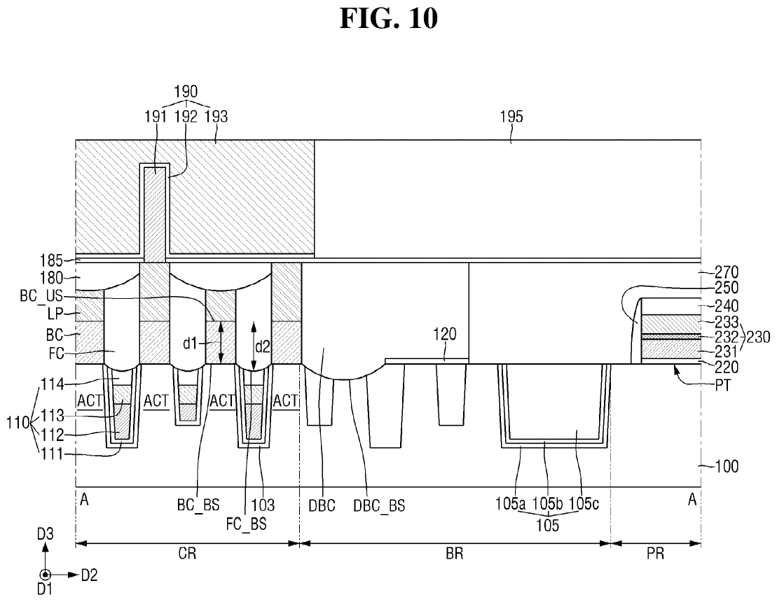

Referring to FIG. 10, the cell buffer film 120 may be interposed between the substrate 100 of the boundary region BR and a portion of the dummy buried contact DBC. The cell buffer film 120 may not be interposed between the substrate 100 of the boundary region BR and the other portion of the dummy buried contact DBC.

For example, the cell buffer film 120 is not interposed below the dummy buried contact DBC adjacent to the cell region CR. The cell buffer film 120 is interposed below the dummy buried contact DBC adjacent to the peripheral region PR. When the dummy buried contact DBC is formed, only a portion of the cell buffer film 120 may be removed. Accordingly, the cell buffer film 120 may be interposed between a portion of the dummy buried contact DBC and the substrate 100 of the boundary region BR.

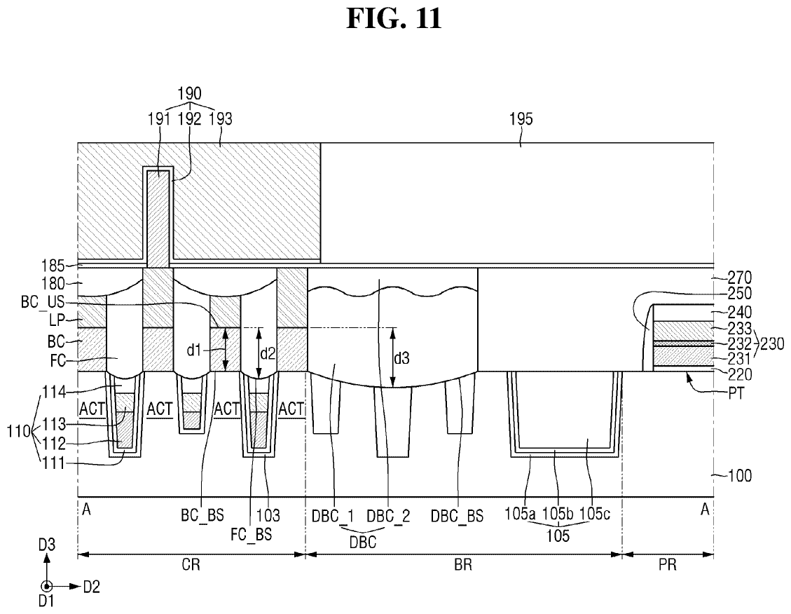

Referring to FIG. 11, the dummy buried contact DBC may include a first portion DBC_1 and a second portion DBC_2.

The second portion DBC_2 of the dummy buried contact DBC may be disposed on the first portion DBC_1 of the dummy buried contact DBC. That is, the first portion DBC_1 of the dummy buried contact DBC may be in contact with a portion of the substrate 100 of the boundary region BR, and the second portion DBC_2 of the dummy buried contact DBC may be in contact with the etch stop film 185.

A boundary between the first portion DBC_1 of the dummy buried contact DBC and the second portion DBC_2 of the dummy buried contact DBC may be an uneven curved surface. This may be because a portion of the first portion DBC_1 of the dummy buried contact DBC is removed in a process of forming the fence FC and the second portion DBC_2 of the dummy buried contact DBC is then formed.

The first portion DBC_1 of the dummy buried contact DBC and the second portion DBC_2 of the dummy buried contact DBC may be made of the same material. As an example, the first portion DBC_1 of the dummy buried contact DBC and the second portion DBC_2 of the dummy buried contact DBC may each be formed as a silicon nitride film. As another example, the first portion DBC_1 of the dummy buried contact DBC and the second portion DBC_2 of the dummy buried contact DBC may be made of different materials.

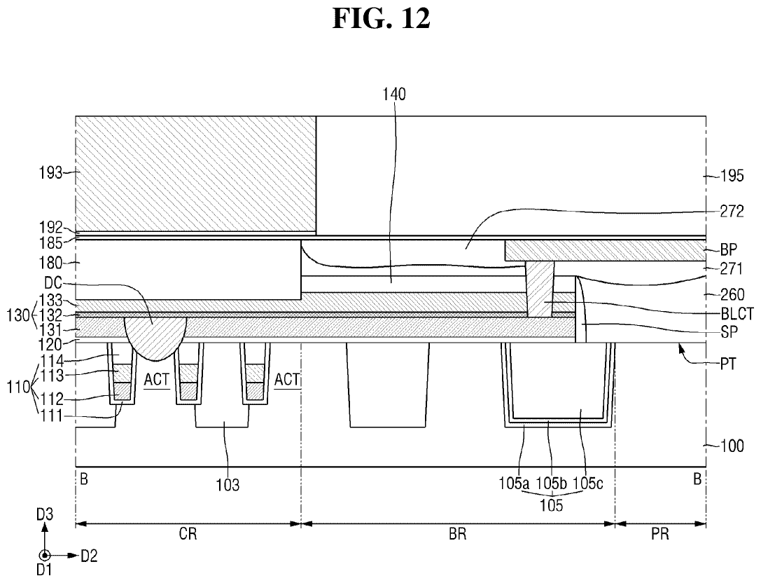

Referring to FIG. 12, the second interlayer insulating film 270 may include a first portion 271 and a second portion 272.

The second portion 272 of the second interlayer insulating film 270 may be disposed on the first portion 271 of the second interlayer insulating film 270. That is, the first portion 271 of the second interlayer insulating film 270 may be in contact with the bit line capping pattern 140, and the second portion 272 of the second interlayer insulating film 270 may be in contact with the etch stop film 185.

In a process of forming the fence FC, a portion of the first portion 271 of the second interlayer insulating film 270 may be removed. Then, the second portion 272 of the second interlayer insulating film 270 may be formed. The first portion 271 of the second interlayer insulating film 270 and the second portion 272 of the second interlayer insulating film 270 may be made of the same material. As an example, the first portion 271 of the second interlayer insulating film 270 and the second portion 272 of the second interlayer insulating film 270 may each be formed as a silicon nitride film. As another example, the first portion 271 of the second interlayer insulating film 270 and the second portion 272 of the second interlayer insulating film 270 may be made of different materials.

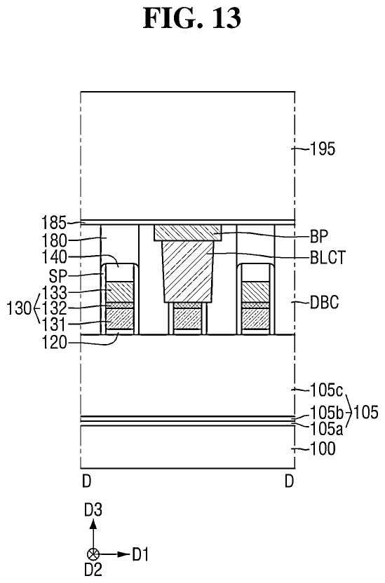

Referring to FIG. 13, at least a portion of the bit line contact BLCT may be in contact with the dummy buried contact DBC. A width of the bit line contact BLCT may be greater than a distance between outer sidewalls of the bit line spacers SP disposed on both sides (e.g., two opposite sidewalls) of the bit line structure 130. Accordingly, the bit line contact BLCT may be electrically connected to the bit line structure 130 and at the same time, at least a portion of the bit line contact BLCT may be in contact with the dummy buried contact DBC.

As described above, because the dummy buried contact DBC is made of the insulating material, a short-circuit does not occur even though the bit line contact BLCT and the dummy buried contact DBC are in contact with each other.

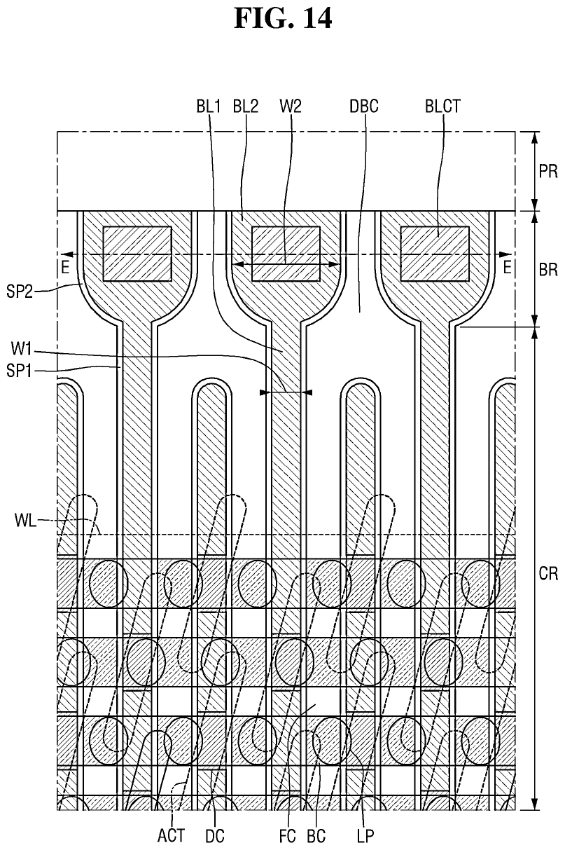

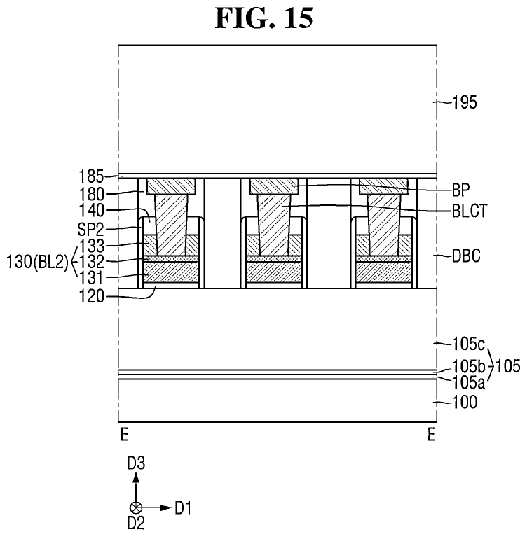

Hereinafter, a semiconductor memory device according to an example embodiment of the present disclosure will be described with reference to FIGS. 14 and 15. For convenience of explanation, contents overlapping those described with reference to FIGS. 1 to 6 will be briefly described or a description thereof will be omitted.

FIG. 14 is a plan view of a semiconductor memory device according to some an example embodiment of the present disclosure. FIG. 15 is a cross-sectional view taken along line E-E in FIG. 14. For reference, FIG. 14 may be a plan view corresponding to portion P1 of FIG. 1.

Referring to FIGS. 14 and 15, each of a plurality of bit lines BL may include a first bit line BL1 and a second bit line BL2.

The first bit line BL1 may extend to be elongated in the second direction D2. The second bit line BL2 may be connected to the first bit line BL1. The first bit line BL1 and the second bit line BL2 may be arranged side by side in the second direction D2.

In some example embodiments, the first bit line BL1 has a first width W1 in the first direction D1. The second bit line BL2 has a second width W2 in the first direction D1. The first width W1 may be smaller than the second width W2. That is, the bit line BL may have a width in the first direction D1 that is constant and then increases from the cell region CR toward the peripheral region PR. A point where the width of the bit line BL in the first direction D1 changes may be a boundary between the first bit line BL1 and the second bit line BL2.

In some example embodiments, the second bit line BL2 may be disposed at an end of one of a pair of first bit lines BL1 most adjacent to each other, but may not be disposed at an end of the other of the pair of first bit lines BL1 most adjacent to each other. The phrase “a pair of bit lines most adjacent to each other” may mean that other bit lines are not disposed between the pair of bit lines.

That is, one first bit line BL1 may be provided between a pair of second bit lines BL2 most adjacent to each other. In this case, the first bit line BL1 does not overlap the pair of second bit lines BL2 most adjacent to each other, in the first direction D1. However, the first bit line BL1 may overlap at least portions of the pair of second bit lines BL2 most adjacent to each other, in the second direction D2.

In other words, a spaced distance between the pair of second bit lines BL2 most adjacent to each other in the first direction D1 may be smaller than the first width W1 of the first bit line BL1 in the first direction D1. However, the inventive concepts of the present disclosure are not limited thereto.

In some example embodiments, the bit line spacer SP may include a first bit line spacer SP1 and a second bit line spacer SP2.

The first bit line spacer SP1 may be disposed on a sidewall of the first bit line BL1. The second bit line spacer SP2 may be disposed on a sidewall of the second bit line BL2. The first bit line spacer SP1 and the second bit line spacer SP2 may be connected to each other.

A spaced distance between a pair of first bit line spacers SP1 may be the first width W1, and a spaced distance between a pair of second bit line spacers SP2 may be the second width W2.

The dummy buried contact DBC may be interposed between the first bit lines BL1 and may be interposed between the second bit lines BL2. The dummy buried contact DBC may include an insulating material. In FIG. 15, each of the bit line contact BLCT and the bit line pad BP may not be in contact with the dummy buried contact DBC. However, the inventive concepts of the present disclosure are not limited thereto.

In a process of forming the bit line contact BLCT, the bit line contact BLCT may be misaligned. Accordingly, the bit line contact BLCT may be in contact with the second bit line spacer SP2 and the dummy buried contact DBC. However, because the second bit line spacer SP2 and the dummy buried contact DBC are made of an insulating material, a short-circuit may not occur.

Hereinafter, a manufacturing method of a semiconductor memory device according to an example embodiment of the present disclosure will be described with reference to FIGS. 16 to 22. FIGS. 16 to 22 are views for describing intermediate steps of a manufacturing method of a semiconductor memory device according to an example embodiment of the present disclosure.

Referring to FIG. 16, the substrate 100 is provided. The substrate 100 includes the cell region CR, the boundary region BR, and the peripheral region PR.

The cell element isolation films 103 and the boundary element isolation films 105 may be formed within the substrate 100. The cell element isolation films 103 may be formed within the substrate 100 of the cell region CR, and the boundary element isolation films 105 may be formed within the substrate 100 of the boundary region BR.

Subsequently, the word line structures 110 may be formed. First, the gate trenches may be formed within the substrate 100 of the cell region CR. The gate trenches may extend to be elongated in the first direction D1. Some portions of the gate trenches may be formed within the cell element isolation films 103. The other portions of the gate trenches may be formed within the substrate 100.

The word line structures 110 may be formed within the gate trenches. First, the gate insulating film 111 may be formed along the profile of the gate trench. Subsequently, the gate electrode 112 may be formed on the gate insulating film 111. Subsequently, the gate capping films 113 and 114 may be formed on the gate electrode 112.

The peripheral circuit element PT may be formed on the substrate 100 of the peripheral region PR. In addition, although not illustrated, the bit line and the direct contact may be formed on the substrate 100 of the cell region CR. The peripheral circuit element PT, the bit line, and the direct contact may be formed through the same process. The peripheral circuit element PT may include the peripheral gate insulating film 220, the peripheral gate structure 230, the peripheral gate capping pattern 240, and the peripheral gate spacer 250. Components of the peripheral gate structure 230 may be disposed at substantially the same levels as components of the bit line structure, respectively.

The second interlayer insulating film 270 covering the peripheral circuit element PT may be formed. In addition, the pre-buried contact PBC may be formed on the cell region CR and a portion of the boundary region BR. The pre-buried contact PBC may be formed between a pair of bit lines BL. The pre-buried contact PBC may be elongated in the second direction d2. The pre-buried contact PBC may include at least one of polysilicon doped with impurities, a conductive silicide compound, conductive metal nitride, or metal.

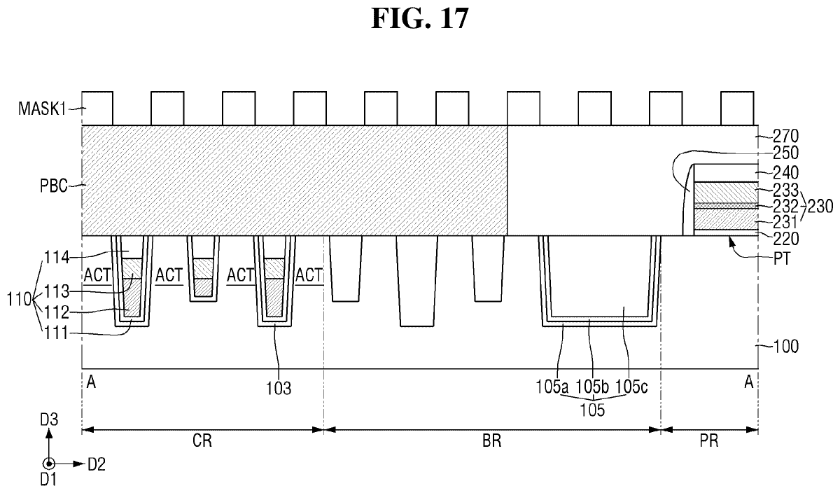

Referring to FIG. 17, a first mask film MASK1 may be formed on the pre-buried contact PBC and the second interlayer insulating film 270. The first mask film MASK1 may have openings roughly defining positions of the fences FC. The first mask film MASK1 may be formed as at least one of a photoresist film, an amorphous carbon layer (ACL), a spin on hardmask (SOH), a spin on carbon (SOC) film, or a silicon nitride film.

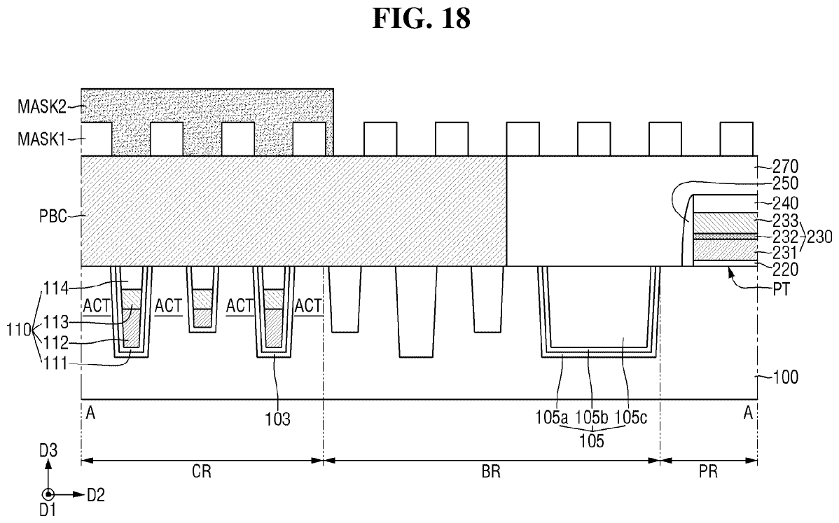

Referring to FIG. 18, a second mask film MASK2 may be formed on the substrate 100 of the cell region CR. The second mask film MASK2 may be made of a material having an etch selectivity with respect to the first mask film MASK1. The second mask film MASK2 may roughly hide or cover positions where the fences FC are to be formed. The second mask film MASK2 may hide a portion of the first mask film MASK1 and expose the other portion of the first mask film MASK1.

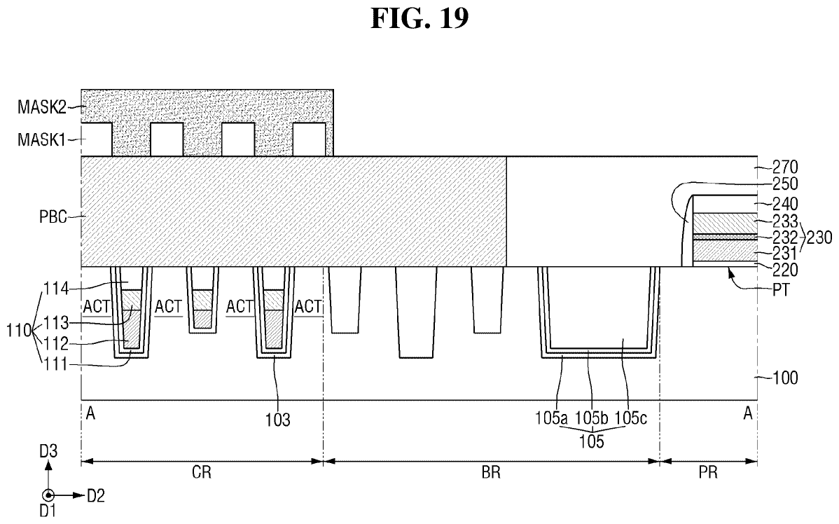

Referring to FIG. 19, a portion of the first mask film MASK1 may be removed. For example, the first mask film MASK1 exposed by the second mask film MASK2 may be removed.

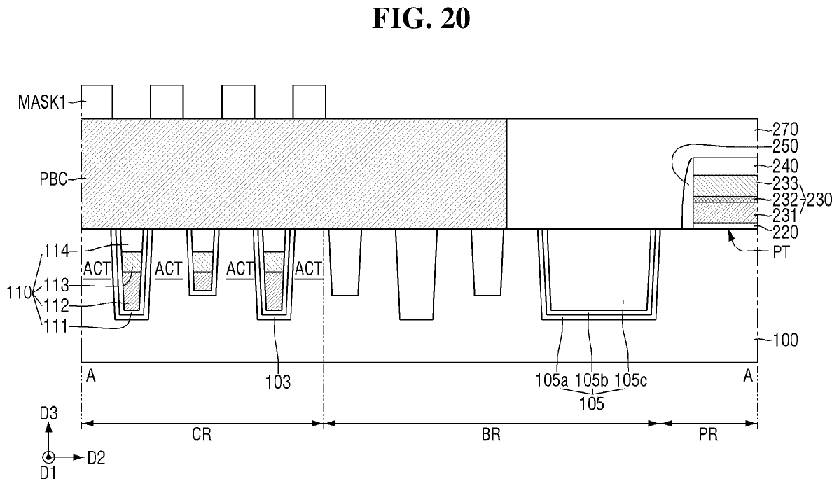

Referring to FIG. 20, the first mask film MASK1 may be exposed by removing the second mask film MASK2.

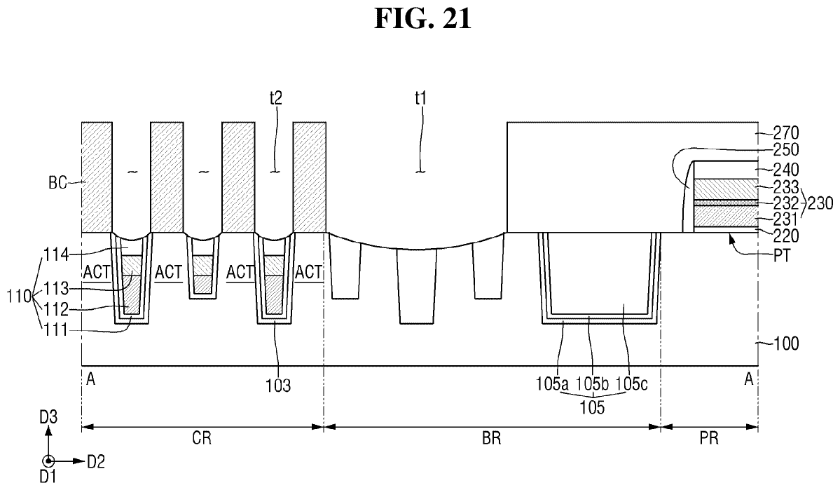

Referring to FIG. 21, the pre-buried contact PBC may be etched using the first mask film MASK1 as an etching mask. The buried contacts BC may be formed by etching the pre-buried contact PBC. In addition, a first trench t1 and second trenches t2 may be formed by etching the pre-buried contact PBC. The first trench t1 and the second trenches t2 may be formed through the same etching process.

The first trench t1 may be a trench for forming a dummy buried contact DBC to be described later. The first trench t1 may be formed on the substrate 100 of the boundary region BR. In a process of forming the first trench t1, a portion of the substrate 100 of the boundary region BR and a portion of the boundary element isolation film 105 may be removed. That is, a bottom surface of the first trench t1 may be a downwardly convex curved surface.

The second trenches t2 may be trenches for forming fences FC to be described later. The second trenches t2 may be formed on the substrate 100 of the cell region CR. For example, the second trenches t2 may be formed on the word line structures 110. In a process of forming the second trench t2, a portion of the word line structure 110 may be removed. That is, a bottom surface of the second trench t2 may be a downwardly convex curved surface.

In some example embodiments, a depth of the first trench t1 may be greater than a depth of the second trench t2. This may be because a width of the first trench t1 is greater than a width of the second trench t2. However, the inventive concepts of the present disclosure is not limited thereto. The depth of the first trench t1 may also be smaller than the depth of the second trench t2.

In some example embodiments, a portion of the second interlayer insulating film 270 may also be removed. The second interlayer insulating film 270 and the pre-buried contact PBC have an etch selectivity with respect to each other, but a portion of the second interlayer insulating film 270 may also be removed in a process of removing the pre-buried contact PBC. In this case, as illustrated in FIG. 12, the second interlayer insulating film 270 may be divided into the first portion 271 and the second portion 272.

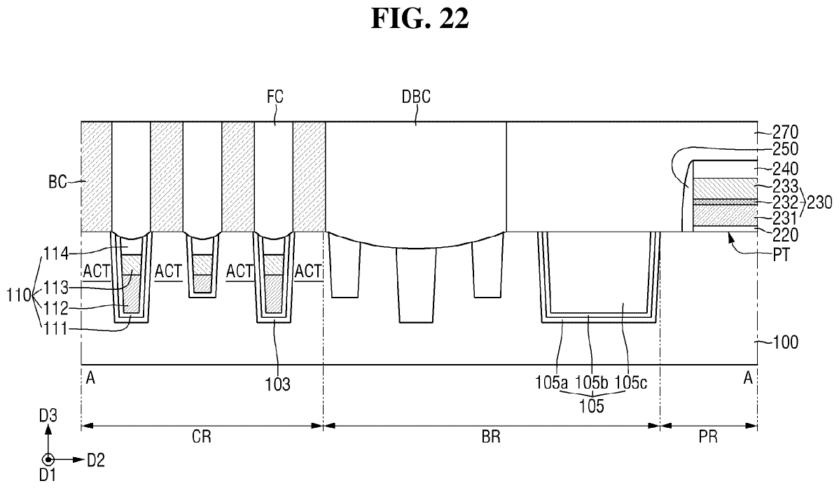

Referring to FIG. 22, the fences FC and the dummy buried contact DBC may be formed. The dummy buried contact DBC may fill the first trench t1. The fences FC may fill the second trenches t2. The fence FC and the dummy buried contact DBC may be formed through the same process. Accordingly, the fence FC and the dummy buried contact DBC may include the same material. As an example, the fence FC and the dummy buried contact DBC may each be formed as a silicon nitride film.

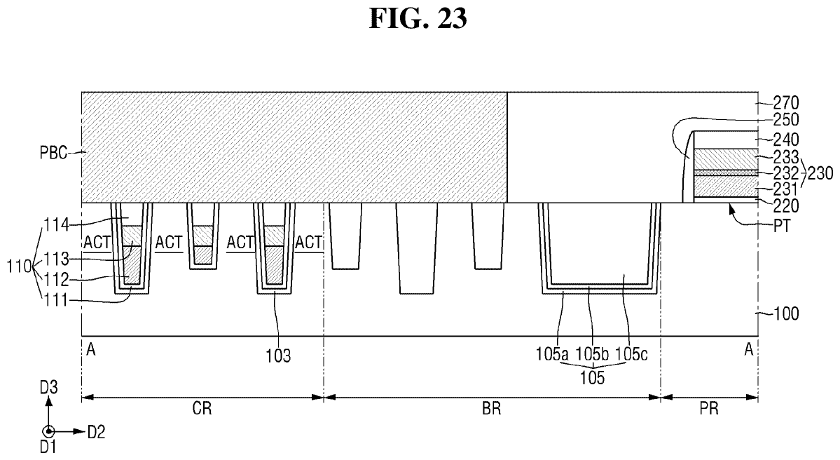

Hereinafter, a manufacturing method of a semiconductor memory device according to an example embodiment of the present disclosure will be described with reference to FIGS. 23 to 28. FIGS. 23 to 28 are views for describing intermediate steps of a manufacturing method of a semiconductor memory device according to an example embodiment of the present disclosure.

Referring to FIG. 23, the substrate 100 is provided. The substrate 100 includes the cell region CR, the boundary region BR, and the peripheral region PR.

The cell element isolation films 103 and the boundary element isolation films 105 may be formed within the substrate 100. Subsequently, the word line structures 110 may be formed. The peripheral circuit element PT may be formed on the substrate 100 of the peripheral region PR.

The pre-buried contact PBC may be formed on the cell region CR and a portion of the boundary region BR. The pre-buried contact PBC may be formed between a pair of bit lines BL. The pre-buried contact PBC may be elongated in the second direction d2. The pre-buried contact PBC may include at least one of polysilicon doped with impurities, a conductive silicide compound, conductive metal nitride, or metal.

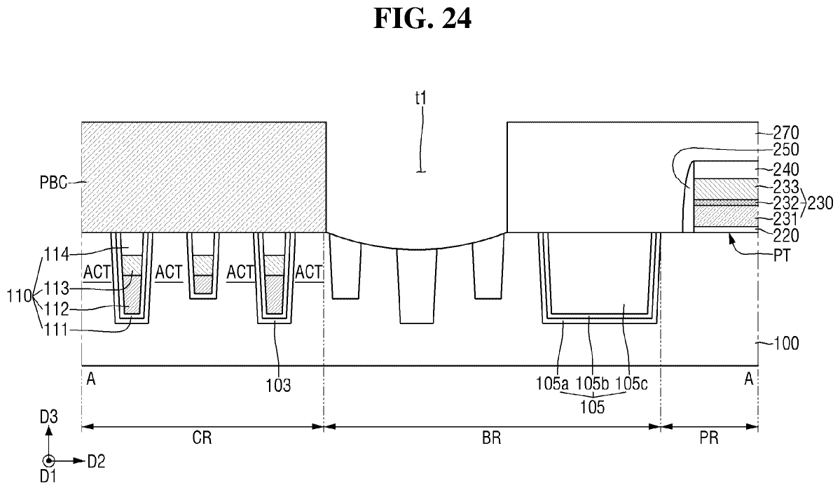

Referring to FIG. 24, a first trench t1 may be formed. The first trench t1 may be formed at a position where the dummy buried contact DBC is to be disposed. Although not illustrated in FIG. 24, the cell buffer film 120 may be disposed on the substrate 100 of the boundary region BR. As illustrated in FIG. 24, the cell buffer film 120 may be removed in a process of forming the first trench t1. However, the inventive concepts of the present disclosure are not limited thereto. According to some example embodiments, the cell buffer film 120 may remain in the process of forming the first trench t1.

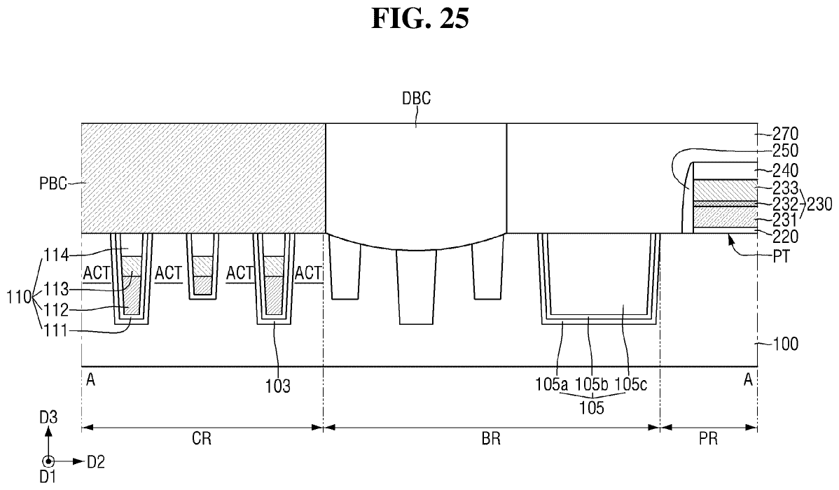

Referring to FIG. 25, the dummy buried contact DBC may be formed. The dummy buried contact DBC may fill the first trench t1. The dummy buried contact DBC may be formed as a silicon nitride film, but the inventive concepts of the present disclosure are not limited thereto.

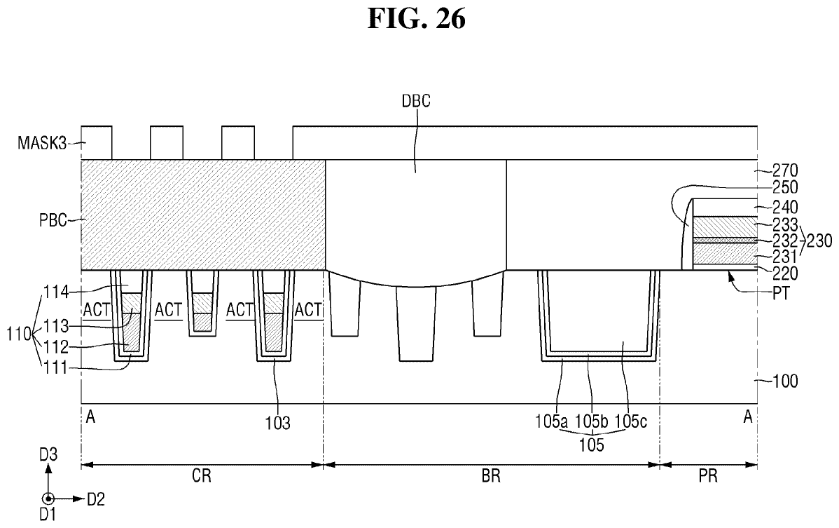

Referring to FIG. 26, a third mask film MASK3 may be formed on the pre-buried contact PBC, the dummy buried contact DBC, and the second interlayer insulating film 270. The third mask film MASK3 may have openings roughly defining positions of the fences FC. The third mask film MASK3 may be formed as at least one of a photoresist film, an amorphous carbon layer (ACL), a spin on hardmask (SOH), a spin on carbon (SOC) film, or a silicon nitride film.

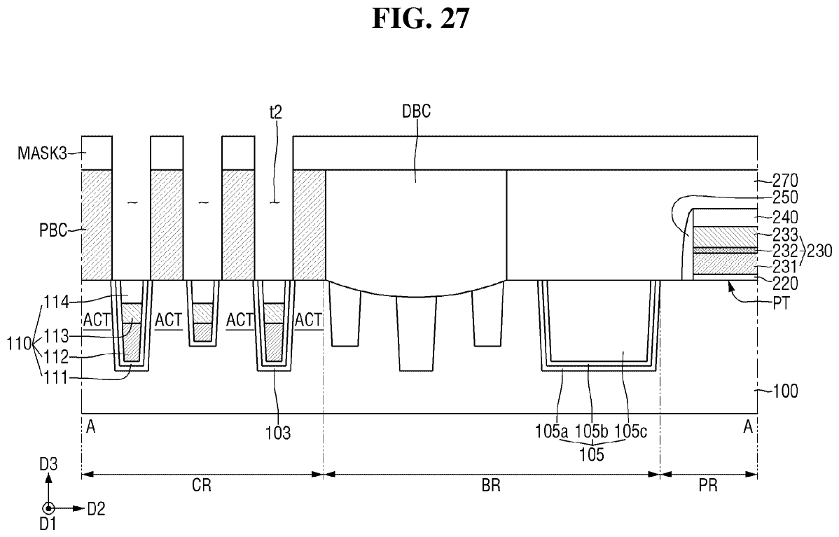

Referring to FIG. 27, the pre-buried contact PBC may be etched using the third mask film MASK3 as an etching mask. The buried contacts BC may be formed by etching the pre-buried contact PBC. In addition, second trenches t2 may be formed by etching the pre-buried contact PBC. The second trenches t2 may be formed on the word line structures 110.

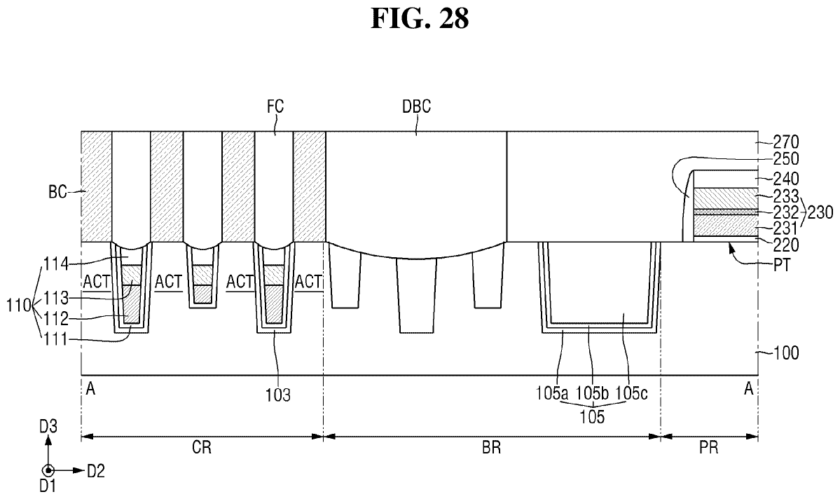

Referring to FIG. 28, the fences FC may be formed. The fences FC may fill the second trenches t2. The fence FC may not be formed through the same process as the dummy buried contact DBC. Accordingly, the fence FC and the dummy buried contact DBC may include different materials. However, the inventive concepts of the present disclosure are not limited thereto. Even though the fence FC and the dummy buried contact DBC are formed through different processes, the fence FC and the dummy buried contact DBC may also be made of the same material.

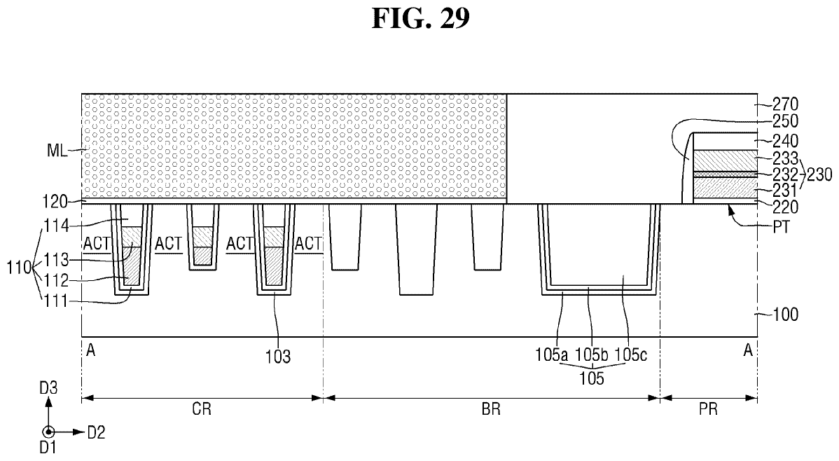

Hereinafter, a manufacturing method of a semiconductor memory device according to an example embodiment of the present disclosure will be described with reference to FIGS. 29 to 35. FIGS. 29 to 35 are views for describing intermediate steps of a manufacturing method of a semiconductor memory device according to an example embodiment of the present disclosure.

Referring to FIG. 29, the substrate 100 is provided. The substrate 100 includes the cell region CR, the boundary region BR, and the peripheral region PR.

The cell element isolation films 103 and the boundary element isolation films 105 may be formed within the substrate 100. The cell element isolation films 103 may be formed within the substrate 100 of the cell region CR, and the boundary element isolation films 105 may be formed within the substrate 100 of the boundary region BR.

Subsequently, the word line structures 110 may be formed. First, the gate trenches may be formed within the substrate 100 of the cell region CR. The gate trenches may extend to be elongated in the first direction D1. Some portions of the gate trenches may be formed within the cell element isolation films 103. The other portions of the gate trenches may be formed within the substrate 100.

The word line structures 110 may be formed within the gate trenches. First, the gate insulating film 111 may be formed along the profile of the gate trench. Subsequently, the gate electrode 112 may be formed on the gate insulating film 111. Subsequently, the gate capping films 113 and 114 may be formed on the gate electrode 112.

The peripheral circuit element PT may be formed on the substrate 100 of the peripheral region PR. In addition, although not illustrated, the bit line and the direct contact may be formed on the substrate 100 of the cell region CR. The peripheral circuit element PT, the bit line, and the direct contact may be formed through the same process. The peripheral circuit element PT may include the peripheral gate insulating film 220, the peripheral gate structure 230, the peripheral gate capping pattern 240, and the peripheral gate spacer 250. Components of the peripheral gate structure 230 may be disposed at substantially the same levels as components of the bit line structure, respectively.

The cell buffer film 120 formed on the substrate 100 of the cell region CR and the boundary region BR may be exposed. A mold film ML may be formed on the cell buffer film 120. The mold film ML may be made of, for example, an oxide-based insulating material. As an example, the mold film ML may be formed as a silicon oxide film.

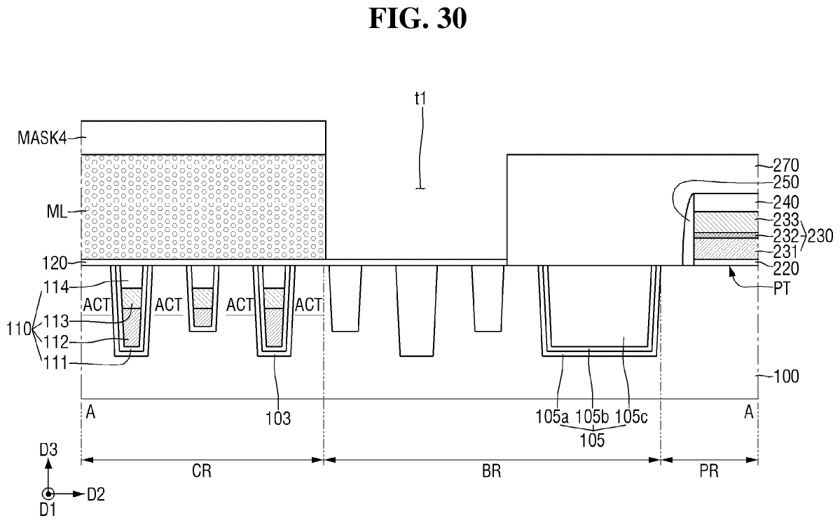

Referring to FIG. 30, a fourth mask film MASK4 may be formed on the mold film ML. The fourth mask film MASK4 may have an opening roughly defining a position of the dummy buried contact DBC. The fourth mask film MASK4 may be formed as at least one of a photoresist film, an amorphous carbon layer (ACL), a spin on hardmask (SOH), a spin on carbon (SOC) film, or a silicon nitride film.

Subsequently, a portion of the mold film ML may be removed using the fourth mask film MASK4 as an etching mask. A first trench t1 may be formed by removing a portion of the mold film ML. The first trench t1 may expose the cell buffer film 120.

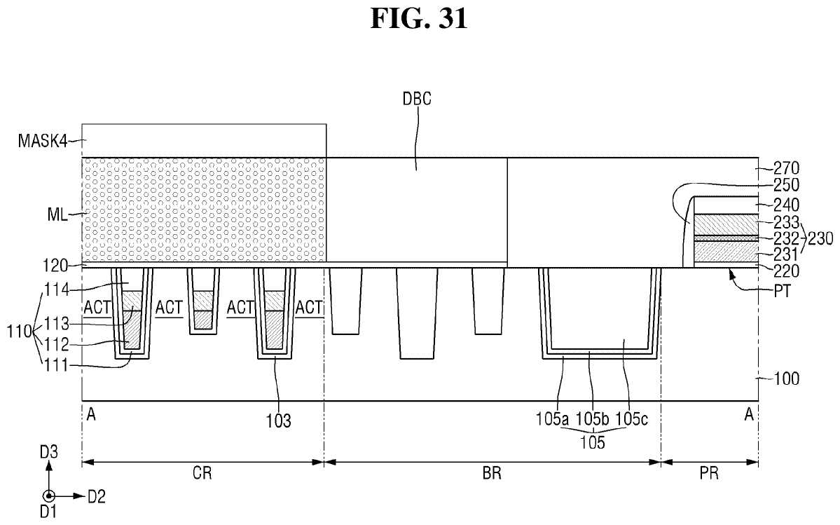

Referring to FIG. 31, the dummy buried contact DBC may be formed. The dummy buried contact DBC may fill the first trench t1. The dummy buried contact DBC may be formed as a silicon nitride film.

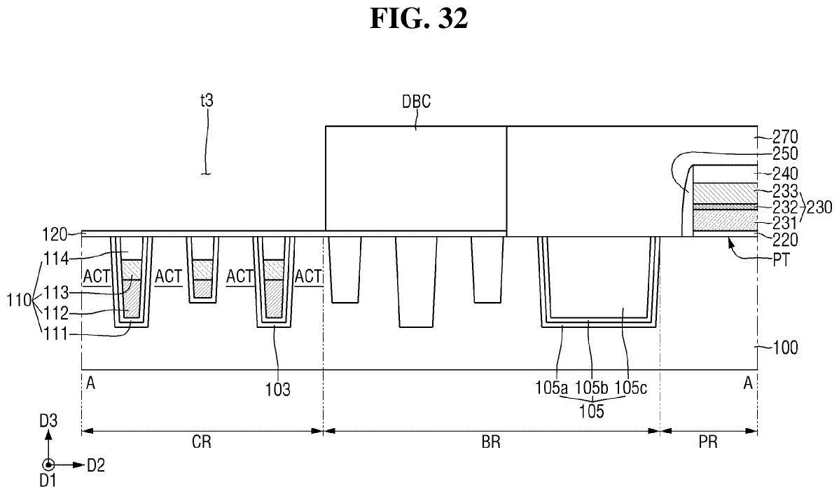

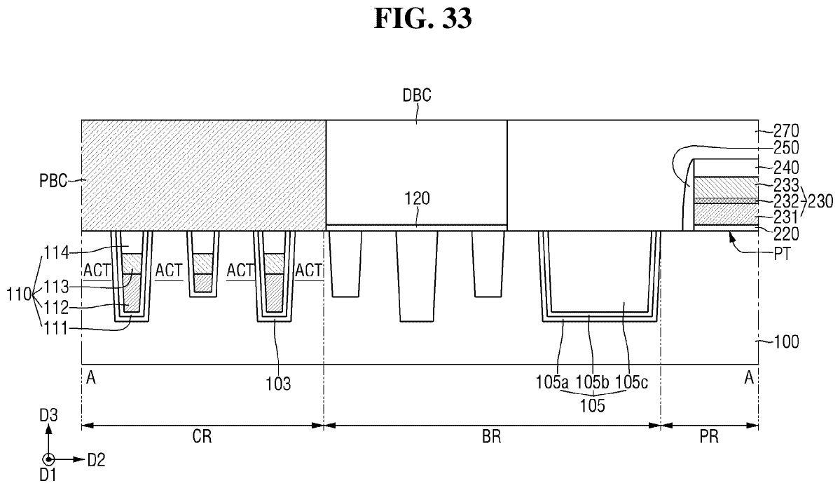

Referring to FIG. 32, the fourth mask film MASK4 may be removed. Subsequently, a third trench t3 may be formed. The third trench t3 may be formed by removing the mold film ML. That is, the third trench t3 may be a space where the mold film ML is removed. When the third trench t3 is formed, the cell buffer film 120 may also be removed (see FIG. 33). That is, the third trench t3 may expose portions of the substrate 100 of the cell region CR and an upper surface of the word line structure 110, and an upper surface of the cell element isolation film 103.

Referring to FIG. 33, the pre-buried contact PBC may be formed. The pre-buried contact PBC may be formed in the third trench t3. The pre-buried contact PBC may include at least one of polysilicon doped with impurities, a conductive silicide compound, conductive metal nitride, or metal.

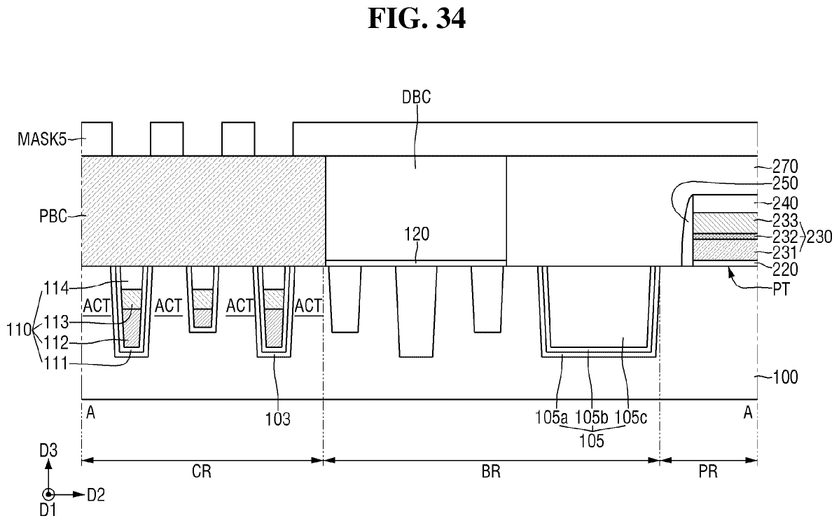

Referring to FIG. 34, a fifth mask film MASK5 may be formed on the pre-buried contact PBC, the dummy buried contact DBC, and the second interlayer insulating film 270. The fifth mask film MASK5 may have openings roughly defining positions of the fences FC. The fifth mask film MASK5 may be formed as at least one of a photoresist film, an amorphous carbon layer (ACL), a spin on hardmask (SOH), a spin on carbon (SOC) film, or a silicon nitride film.

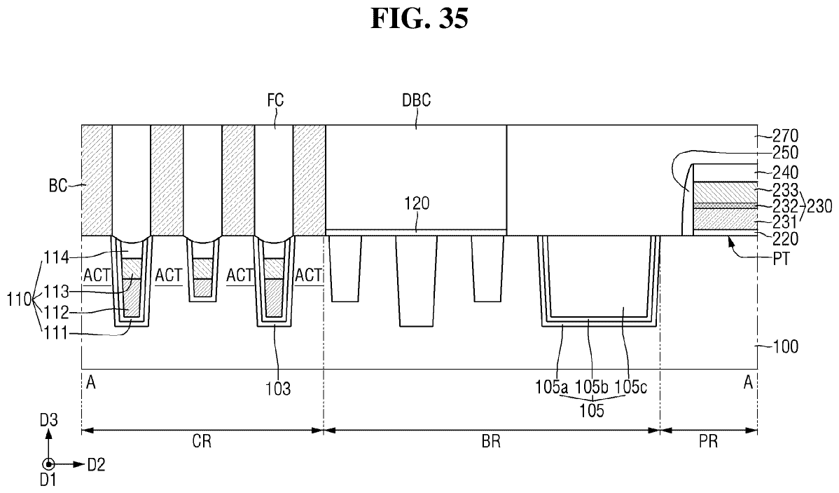

Referring to FIG. 35, the pre-buried contact PBC may be etched using the fifth mask film MASK5 as an etching mask. The buried contacts BC may be formed by etching the pre-buried contact PBC. In addition, second trenches may be formed by etching the pre-buried contact PBC. The second trenches may be formed on the word line structures 110.

The fences FC may be formed in the second trenches. The fence FC may not be formed through the same process as the dummy buried contact DBC. Accordingly, the fence FC and the dummy buried contact DBC may include different materials. However, the inventive concepts of the present disclosure are not limited thereto. Even though the fence FC and the dummy buried contact DBC are formed through different processes, the fence FC and the dummy buried contact DBC may also be made of the same material.

Some example embodiments of the present disclosure have been described hereinabove with reference to the accompanying drawings, but the present disclosure is not limited to the above-described example embodiments, and may be implemented in various different forms, and one of ordinary skill in the art to which the present disclosure pertains may understand that the present disclosure may be implemented in other specific forms without changing the technical spirit, inventive concepts, or essential features of the present disclosure. Therefore, it is to be understood that the example embodiments described above are illustrative rather than being restrictive in all aspects.

What is claimed is:

1. A semiconductor memory device comprising:
a substrate including a cell region, a peripheral region, and a boundary region between the cell region and the peripheral region;
a plurality of gate electrodes extending in a first direction, within the substrate of the cell region;
a plurality of bit lines extending in a second direction crossing the first direction, on the substrate of the cell region and the boundary region;
a plurality of buried contacts connected to the substrate of the cell region and between the gate electrodes and between the bit lines, on the substrate of the cell region;
a dummy buried contact between the bit lines, on the substrate of the boundary region; and
a bit line contact connected to at least one of the bit lines, on the substrate of the boundary region,
wherein the dummy buried contact includes an insulating material.

2. The semiconductor memory device of claim 1, further comprising:
a fence between a corresponding pair of the bit lines and between a corresponding pair of the buried contacts,
wherein the fence includes a same material as the dummy buried contact.

3. The semiconductor memory device of claim 2, wherein a first distance from an upper surface of a respective one of the buried contacts to a bottom surface of the respective one of the buried contacts is smaller than a second distance from the upper surface of the respective one of the buried contacts to a bottom surface of the fence.

4. The semiconductor memory device of claim 3, wherein a third distance from the upper surface of the respective one of the buried contacts to a bottom surface of the dummy buried contact is equal to the second distance.

5. The semiconductor memory device of claim 3, wherein a third distance from the upper surface of the respective one of the buried contacts to a bottom surface of the dummy buried contact is different from the second distance.

6. The semiconductor memory device of claim 1, further comprising:
a cell buffer film between the dummy buried contact and the substrate of the boundary region.

7. The semiconductor memory device of claim 1, wherein a level of a bottom surface of a respective one of the buried contacts is different from a level of a bottom surface of the dummy buried contact.

8. The semiconductor memory device of claim 1, wherein a level of a bottom surface of a respective one of the buried contacts is same as a level of a bottom surface of the dummy buried contact.

9. The semiconductor memory device of claim 1, wherein at least a portion of the bit line contact is in contact with the dummy buried contact.

10. The semiconductor memory device of claim 1, wherein
the bit line contact includes a first contact connected to one of the bit lines and a second contact connected to another of the bit lines, and
at least one of the bit lines is between the first contact and the second contact.

11. A semiconductor memory device comprising:
a substrate including a cell region, a peripheral region, and a boundary region between the cell region and the peripheral region, the cell region including a capacitor, the peripheral region including a peripheral circuit element;
a plurality of gate electrodes extending in a first direction, within the substrate of the cell region;
a plurality of first bit lines extending in a second direction crossing the first direction, on the substrate of the cell region;
a plurality of second bit lines connected to the first bit lines, respectively, on the substrate of the boundary region;
a plurality of fences and a plurality of buried contacts alternately arranged in the second direction, between the first bit lines;
a dummy buried contact between the second bit lines; and
a bit line contact in contact with at least some of the second bit lines, on the substrate of the boundary region,
wherein a width of a respective one of the first bit lines in the first direction is smaller than a width of a respective one of the second bit lines in the first direction, and
the dummy buried contact includes an insulating material.

12. The semiconductor memory device of claim 11, further comprising:
a pair of second bit line spacers on two opposite sidewalls of each of the second bit lines, respectively,
wherein at least one of the second bit line spacers is in contact with the dummy buried contact.

13. The semiconductor memory device of claim 12, further comprising:
a pair of first bit line spacers on two opposite sidewalls of each of the first bit lines, respectively,
wherein the pair of first bit line spacers are connected to the pair of second bit line spacers, respectively.

14. The semiconductor memory device of claim 11, wherein a level of a bottom surface of a respective one of the fences is same as a level of a bottom surface of the dummy buried contact.

15. The semiconductor memory device of claim 11, wherein a material included in the fences is same as a material included in the dummy buried contact.

16. The semiconductor memory device of claim 15, wherein a first distance from an upper surface of a respective one of the buried contacts to a bottom surface of the respective one of the buried contacts is smaller than a second distance from the upper surface of the respective one of the buried contacts to a bottom surface of a respective one of the fences.

17. The semiconductor memory device of claim 11, further comprising:
a cell buffer film between the dummy buried contact and the substrate of the boundary region.

18. The semiconductor memory device of claim 11, wherein at least a portion of the bit line contact is in contact with the dummy buried contact.

19. The semiconductor memory device of claim 11, wherein
the substrate of the cell region includes impurity regions between the gate electrodes, and
the buried contacts are connected to the impurity regions, respectively.

20. A semiconductor memory device comprising:
a substrate including a cell region, a peripheral region, and a boundary region between the cell region and the peripheral region;
a peripheral circuit element on the substrate of the peripheral region;
a plurality of gate electrodes extending in a first direction, within the substrate of the cell region;
a plurality of bit lines extending in a second direction crossing the first direction, on the substrate of the cell region and the boundary region;
a plurality of buried contacts on the substrate of the cell region and spaced apart from each other in the second direction, the buried contacts connected to the substrate of the cell region, the buried contacts being between the gate electrodes and between the bit lines;
a plurality of capacitors connected to the buried contacts, respectively, on the substrate of the cell region;
a plurality of fences between the buried contacts and between the gate electrodes, the fences spaced apart from each other in the second direction and being on the substrate of the cell region;
a dummy buried contact between the bit lines, on the substrate of the boundary region; and
a bit line contact connected to at least one of the bit lines, on the substrate of the boundary region,
wherein a first distance from an upper surface of a respective one of the buried contacts to a bottom surface of the respective one of the buried contacts is smaller than a second distance from the upper surface of the respective one of the buried contacts to a bottom surface of a respective one of the fences,
at least a portion of the dummy buried contacts is in contact with the substrate of the boundary region, and
the dummy buried contacts and the fences include a same material.

21.-30. (canceled)
